(19) United States
(12) Patent Application Publication
(10) Pub. No.: US 2026/0179701 A1
(43) Pub. Date: Jun. 25, 2026

(54) READ-ONLY MEMORY (ROM) DEVICE AND METHOD

(71) Applicant: TAIWAN SEMICONDUCTOR MANUFACTURING COMPANY, LTD., Hsinchu (TW)

(72) Inventors: Hiromasa OTSUBO, Hsinchu (TW); Chien-Ying CHEN, Hsinchu (TW); Preciliano Asinas RUIZ, JR., Hsinchu (TW); Kazumasa UNO, Hsinchu (TW); Hidemitsu KOJIMA, Hsinchu (TW); Tai-Te CHU, Hsinchu (TW)

(21) Appl. No.: 19/090,729

(22) Filed: Mar. 26, 2025

Related U.S. Application Data
(60) Provisional application No. 63/738,200, filed on Dec. 23, 2024.

(51) Int. Cl. G11C 17/12; H10B 20/00

(52) U.S. Cl. CPC G11C 17/12; H10B 20/387

(57) ABSTRACT

A read-only memory (ROM) device includes an active region extending along a first direction, and a plurality of gates extending across and over the active region, along a second direction transverse to the first direction. The plurality of gates correspondingly configures, together with the active region, a plurality of transistors. Each of the plurality of transistors is configured to store a datum. The active region extends continuously across and under more than four conductive gates among the plurality of gates

### RELATED APPLICATION(S)

This application claims the benefit of U.S. Provisional Application No. 63/738,200, filed Dec. 23, 2024, which is incorporated herein by reference in its entirety.

### BACKGROUND

An integrated circuit (“IC”) device includes one or more semiconductor devices represented in an IC layout diagram (also referred to as “layout diagram”, “IC layout”, or “layout”). A layout diagram is hierarchical and includes modules which carry out higher-level functions in accordance with the IC device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. Examples of IC devices and cells correspondingly include memory devices and memory cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic block diagram of a memory device, in accordance with some embodiments.

FIGS. 2A, 2B, 2C, 2D, 2E, 2F, 2G are schematic circuit diagrams of various memory cells, in accordance with some embodiments.

FIG. 3A is a schematic circuit diagram of a circuit region of a memory device, in accordance with some embodiments.

FIG. 3B is a schematic view of a layout of a circuit region of a memory device, in accordance with some embodiments.

FIG. 3C is a schematic cross-sectional view of a circuit region of a memory device, in accordance with some embodiments.

FIG. 4 is a schematic view of a layout of a circuit region of a memory device, in accordance with some embodiments.

FIGS. 5A, 5B, 5C, 5D, 5E each include a schematic circuit diagram and a schematic view of a layout of a circuit region of a memory device, in accordance with some embodiments.

FIGS. 6A, 6B, 6C, 6D, 6E, 6F each include a schematic circuit diagram and a schematic view of a layout of a circuit region of a memory device, in accordance with some embodiments.

FIGS. 7A, 7B, 7C, 7D are flow charts of various methods, in accordance with some embodiments.

FIG. 8 is a block diagram of an electronic design automation (EDA) system in accordance with some embodiments.

FIG. 9 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a read-only memory (ROM) device, or a layout thereof, comprises a plurality of instances of a circuit region, or a ROM cell, arranged in abutment. The ROM device, or the layout, comprises an active region extending continuously across multiple abutting instances of the circuit region, or the ROM cell, without being interrupted or discontinued by one or more isolation structures inside, or between, the multiple instances.

Compared to other approaches where such isolation structures exist inside and/or between abutting instances of a circuit region or a ROM cell, a size of a ROM device in one or more embodiments is advantageously reduced. In a non-limiting example, a 4×4 ROM cell in accordance with some embodiments has a width of 4 gate pitches (sometimes referred to as “CPP”), whereas a 4×4 ROM cell in accordance with the other approaches has greater width of 5 CPPs or 6 CPPs. As a result, it is possible for a ROM device including 4-CPP 4×4 ROM cells in accordance with one or more embodiments to achieve an area reduction of about 16.7% compared to a ROM device including 5-CPP 4×4 ROM cells, or about 33.3% compared to a ROM device including 6-CPP 4×4 ROM cells in accordance with the other approaches. In some embodiments, it is possible to achieve one or more further advantages including, but not limited to, reduced bit line length, lower variable bit line leakage, reduced Poly Extension Effect (PXE), or the like.

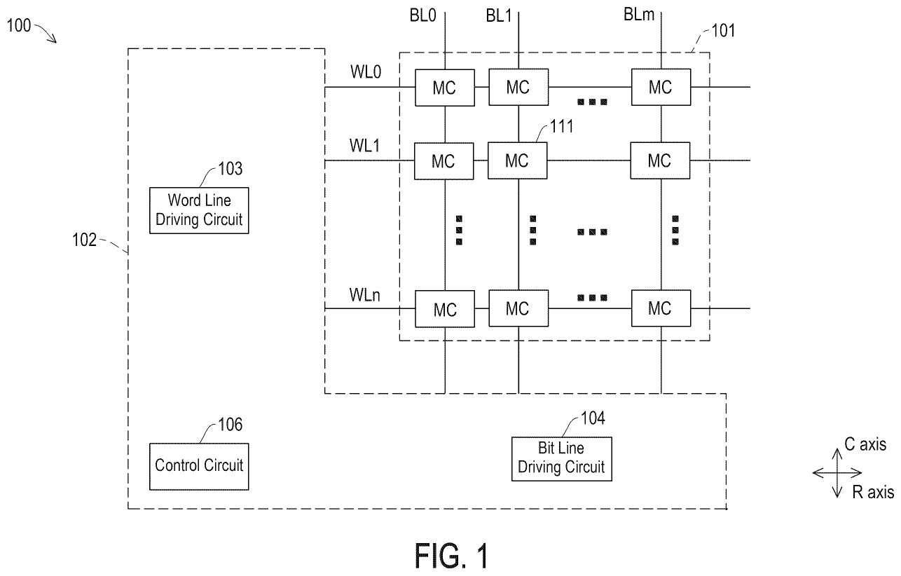

FIG. 1 is a schematic block diagram of a memory device 100, in accordance with some embodiments. A memory device is a type of an IC device. In at least one embodiment, a memory device is an individual IC device. In some embodiments, a memory device is included as a part of a larger IC device which comprises circuitry other than the memory device for other functionalities. The memory device 100 is a read-only memory (ROM) device, in one or more embodiments.

The memory device 100 comprises a memory array 101 of a plurality of memory cells MC, and a memory controller 102 (sometimes referred to as “memory control circuitry”) coupled to control an operation of the memory cells MC. In a ROM device in accordance with some embodiments, each memory cell MC is configured to store one bit and is sometimes referred to as a bitcell, and the memory array 101 is referred to as ROM array. In the memory array 101, the memory cells MC are arranged in a plurality of columns and a plurality of rows. The number of columns in the memory array 101 is the same as, or different from, the number of rows. Columns and rows in a memory array are sometimes referred to as memory columns and memory rows. The memory columns extend in a column direction, designated as C axis in the drawings. The memory rows extend in a row direction transverse to the column direction, and designated as R axis in the drawings.

The memory device 100 further comprises a plurality of word lines WL0, WL1, . . . WLn extending along the rows of the memory array 101, and a plurality of bit lines BL0, BL1, . . . BLm extending along the columns of the memory array 101. The word lines are commonly referred to herein with a label WL, and the bit lines are commonly referred to herein with a label BL. The word lines are configured for transmitting addresses of memory cells MC to be read from. The word lines are sometimes referred to as “address lines.” The bit lines are configured for transmitting data read from the memory cells MC indicated by the addresses on the corresponding word lines. The bit lines are sometimes referred to as “data lines.” Various numbers of word lines and/or bit lines in the memory device 100 are within the scope of various embodiments. Memory cells MC in each memory row are electrically coupled to the memory controller 102 by a corresponding word line, whereas memory cells MC in each memory column are electrically coupled to the memory controller 102 by a corresponding bit line. For example, a memory cell 111 in the memory array 101 is coupled to the memory controller 102 by the corresponding word line WL1, and the corresponding bit line BL1.

In the example configuration in FIG. 1, the memory controller 102 comprises a word line driving circuit 103 (sometimes referred to as a row decoder or a row decoder circuit), a bit line driving circuit 104 (sometimes referred to as a column decoder or a column decoder circuit), and a control circuit 106. Various quantities of word line driving circuits, and/or bit line driving circuits are within the scopes of various embodiments.

The word line driving circuit 103 is configured to decode a row address of one or more memory cells MC selected to be accessed in a read operation. For example, the word line driving circuit 103 comprises a plurality of word line drivers, or the like, each coupled to one or more word lines of the memory array 101. The word line driving circuit 103 is configured to supply, through the corresponding word line drivers, or the like, a set of access voltages to the selected word line(s) corresponding to the decoded row address, and a different set of voltages (e.g., zero) to the other, unselected word lines.

The bit line driving circuit 104 is configured to decode a column address of one or more memory cells MC selected to be accessed in a read operation. In some embodiments, the bit line driving circuit 104 comprises one or more bit line multiplexers each coupled to one or more bit lines of the memory array 101. In some embodiments, the bit line driving circuit 104 is configured to supply, through the bit line multiplexers, a set of voltages to the selected bit line(s) corresponding to the selected memory cells MC to be accessed, and a different set of voltages to the other, unselected bit lines. In at least one embodiment, unselected bit lines are left floating. For example, the bit line driving circuit 104 comprises one or more pre-charging circuits configured to pre-charge the selected bit line(s) to a pre-charge voltage in a read operation. In some embodiments, the selected bit line(s) is/are not pre-charged. The bit line driving circuit 104 is configured to couple the selected bit line(s) corresponding to the selected memory cells MC to be accessed, to an output circuit (not shown), a sense amplifier (not shown), or the like in the memory controller 102, so as to read out the data stored in the selected memory cells MC.

In an example read operation, the memory cell 111 is selected to be accessed. As a result, the corresponding word line WL1 is the selected word line, and the corresponding bit line BL1 is the selected bit line. The word line driving circuit 103 is configured to supply an access voltage (e.g., VDD) to the selected word line WL1, and a different voltage (e.g., zero or VSS) to the other, unselected word lines. The bit line driving circuit 104 is configured to supply a pre-charge voltage (e.g., VDD) to the selected bit line BL1, and couple the selected bit line BL1 to the output circuit or sense amplifier. Upon application of the access voltage through the word line WL1 to the memory cell 111, the pre-charge voltage on the bit line BL1 either remains unchanged, or is pulled to VSS, depending on a datum or bit stored in the memory cell 111. The voltage on the bit line BL1 is supplied to the output circuit or sense amplifier, whereby the datum or bit stored in the memory cell 111 is read out.

The control circuit 106 is configured to control operations of the word line driving circuit 103, bit line driving circuit 104, an output circuit, a sense amplifier and/or other components in the memory controller 102. In at least one embodiment, the memory controller 102 further includes one or more clock generators for providing clock signals for various components of the memory device 100, one or more input/output (I/O) circuits for data, clock and/or control exchange with an external device or circuitry, and/or one or more sub-controllers for controlling various operations in the memory device 100. The described memory device configuration is an example, and other memory device configurations are within the scopes of various embodiments.

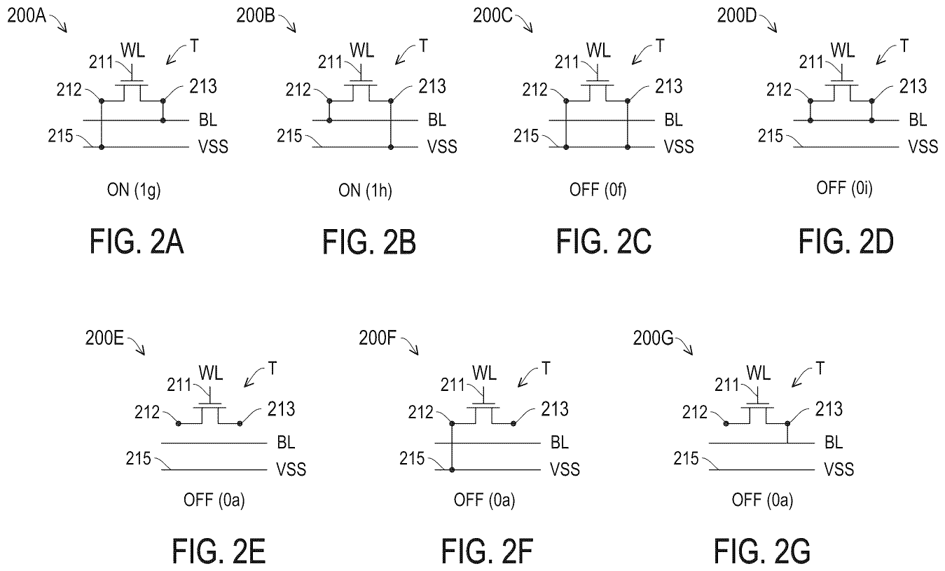

FIGS. 2A-2G are schematic circuit diagrams of various memory cells 200A-200G, in accordance with some embodiments. In some embodiments, one or more of the memory cells 200A-200G correspond to one or more of the memory cells MC described with respect to FIG. 1. For simplicity, corresponding components in FIGS. 2A-2G are designated by the same reference numerals.

The memory cells 200A-200B are examples of memory cells configured to store a first logic value, and the memory cells 200C-200G are examples of memory cells configured to store a second logic value different from the first logic value. In specific examples described herein, the first logic value is logic “1” and the second logic value is logic “0”. Other configurations where the first logic value is logic “0” and the second logic value is logic “1” are within the scopes of various embodiments. The memory cells 200A-200G are sometimes referred to as NOR-type ROM bitcells, and a ROM device including one or more of the memory cells 200A-200G is sometimes referred to as an NOR-type ROM device.

In FIG. 2A, the memory cell 200A comprises a transistor T which has a gate 211, a first source/drain 212, and a second source/drain 213. The gate 211 is electrically coupled to a word line WL, the first source/drain 212 is electrically coupled to a power rail 215, and the second source/drain 213 is electrically coupled to a bit line BL. In at least one embodiment, the word line WL corresponds to one or more of the word lines, and the bit line BL corresponds to one or more of the bit lines described with respect to FIG. 1. The power rail 215 is configured to carry a power supply voltage for a read operation of the memory cell 200A. In the example configurations in FIGS. 2A-2G, the transistor T is an N-type transistor and the power supply voltage carried by the power rail 215 is the ground voltage, or VSS. The power rail 215 configured to carry VSS is referred to herein as a VSS power rail. Other configurations are within the scopes of various embodiments. For example, when the transistor T is a P-type transistor, the power rail 215 is configured to carry a positive voltage, e.g., VDD, or the like. Examples of the transistor T include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. In one or more non-limiting embodiments specifically described herein, all transistors in a ROM array are N-type transistors, such as NMOS transistors.

In an example read operation of the memory cell 200A in accordance with some embodiments, an access voltage (e.g., VDD) is supplied through the word line WL to the gate 211 of the transistor T, and the bit line BL is pre-charged to a pre-charge voltage (e.g., VDD). The access voltage turns ON the transistor T, and the turned ON transistor T electrically couples the bit line BL to the VSS power rail. As a result, a voltage on the bit line BL is pulled from the pre-charge voltage (e.g., VDD) down to VSS. The voltage on the bit line BL being pulled down to VSS is output or detected by a sense amplifier, to indicate that logic “1” is stored in the memory cell 200A.

The configuration of the memory cell 200A configured to store logic “1” is referred to herein as an ON configuration. The ON configuration indicates that when the transistor T is turned ON, the turned ON transistor T electrically couples the bit line BL to the VSS power rail. The memory cell 200B is a further example of a memory cell having the ON configuration and configured to stored logic “1”. In contrast, as described herein, memory cells 200C-200G are examples of memory cells having an OFF configuration and configured to stored logic “0”. The OFF configuration indicates that when the transistor T is turned ON, the turned ON transistor T does not electrically couple the bit line BL to the VSS power rail.

The ON configuration of the memory cell 200A in which the first source/drain 212 is electrically coupled to the VSS power rail and the second source/drain 213 is electrically coupled to the bit line BL is referred to herein as an ON configuration 1g.

In FIG. 2B, the memory cell 200B is configured to store logic “1” and has an ON configuration. In the memory cell 200B, the first source/drain 212 is electrically coupled to the bit line BL and the second source/drain 213 is electrically coupled to the VSS power rail, and the ON configuration of the memory cell 200B is referred to herein as an ON configuration 1h. In some embodiments, a read operation of the memory cell 200B is similar to that described with respect to the memory cell 200A in that, when the transistor T is turned ON, the turned ON transistor T electrically couples the bit line BL to the VSS power rail, and the voltage on the bit line BL is pulled down from the pre-charge voltage to VSS to indicate that logic “1” is stored in the memory cell 200B.

In FIG. 2C, the memory cell 200C is configured to store logic “0” and has an OFF configuration. In the memory cell 200C, both the first source/drain 212 and the second source/drain 213 are electrically coupled to the VSS power rail, and the OFF configuration of the memory cell 200C is referred to herein as an OFF configuration 0f.

In an example read operation of the memory cell 200C in accordance with some embodiments, an access voltage (e.g., VDD) is supplied through the word line WL to the gate 211 of the transistor T, and the bit line BL is pre-charged to a pre-charge voltage (e.g., VDD). The access voltage turns ON the transistor T. However, because both of the first source/drain 212 and the second source/drain 213 are electrically coupled to the VSS power rail, the turned ON transistor T does not electrically couple the bit line BL to the VSS power rail. As a result, a voltage on the bit line BL remains at the pre-charge voltage (e.g., VDD). The voltage on the bit line BL remaining at the pre-charge voltage is output or detected by a sense amplifier, to indicate that logic “0” is stored in the memory cell 200C.

In FIG. 2D, the memory cell 200D is configured to store logic “0” and has an OFF configuration. In the memory cell 200D, both the first source/drain 212 and the second source/drain 213 are electrically coupled to the bit line BL, and the OFF configuration of the memory cell 200D is referred to herein as an OFF configuration 0i. In some embodiments, a read operation of the memory cell 200D is similar to that described with respect to the memory cell 200C in that, when the transistor T is turned ON, the turned ON transistor T does not electrically couple the bit line BL to the VSS power rail, and the voltage on the bit line BL remains at the pre-charge voltage to indicate that logic “0” is stored in the memory cell 200D.

In FIG. 2E, the memory cell 200E is configured to store logic “0” and has an OFF configuration. In the memory cell 200E, the first source/drain 212 and the second source/drain 213 are not electrically coupled to any of the bit line BL and the VSS power rail. In at least one embodiment, the first source/drain 212 and the second source/drain 213 are electrically floating. In some embodiments, a read operation of the memory cell 200E is similar to that described with respect to the memory cell 200C in that, when the transistor T is turned ON, the turned ON transistor T does not electrically couple the bit line BL to the VSS power rail, and the voltage on the bit line BL remains at the pre-charge voltage to indicate that logic “0” is stored in the memory cell 200E.

In FIG. 2F, the memory cell 200F is configured to store logic “0” and has an OFF configuration. In the memory cell 200F, the first source/drain 212 is electrically coupled to the VSS power rail, but the second source/drain 213 is not electrically coupled to any of the bit line BL and the VSS power rail. In at least one embodiment, the second source/drain 213 is electrically floating. In some embodiments, a read operation of the memory cell 200F is similar to that described with respect to the memory cell 200C in that, when the transistor T is turned ON, the turned ON transistor T does not electrically couple the bit line BL to the VSS power rail, and the voltage on the bit line BL remains at the pre-charge voltage to indicate that logic “0” is stored in the memory cell 200F.

In FIG. 2G, the memory cell 200G is configured to store logic “0” and has an OFF configuration. In the memory cell 200G, the second source/drain 213 is electrically coupled to the bit line BL, but the first source/drain 212 is not electrically coupled to any of the bit line BL and the VSS power rail. In at least one embodiment, the first source/drain 212 is electrically floating. In some embodiments, a read operation of the memory cell 200G is similar to that described with respect to the memory cell 200C in that, when the transistor T is turned ON, the turned ON transistor T does not electrically couple the bit line BL to the VSS power rail, and the voltage on the bit line BL remains at the pre-charge voltage to indicate that logic “0” is stored in the memory cell 200G. The OFF configurations of the memory cells 200E-200G are commonly referred to herein as an OFF configuration Oa.

In some embodiments, at the design stage, a blank or unprogrammed ROM array corresponding to the memory array 101 is developed. In such an unprogrammed ROM array, each memory cell, or bitcell, has the configuration described with respect to FIG. 2E where electrical connections of the first source/drain 212 and second source/drain 213 to the bit line BL and VSS power rail are not yet determined. In a subsequent programming stage, the unprogrammed ROM array is programmed in accordance with predetermined data to be stored in the ROM array. For example, each bitcell in the unprogrammed ROM array is programmed by adding, or not adding, one or more electrical connections in accordance with the datum or bit or logic value to be stored in the bitcell, and in accordance with one of the configurations described with respect to FIGS. 2A-2G.

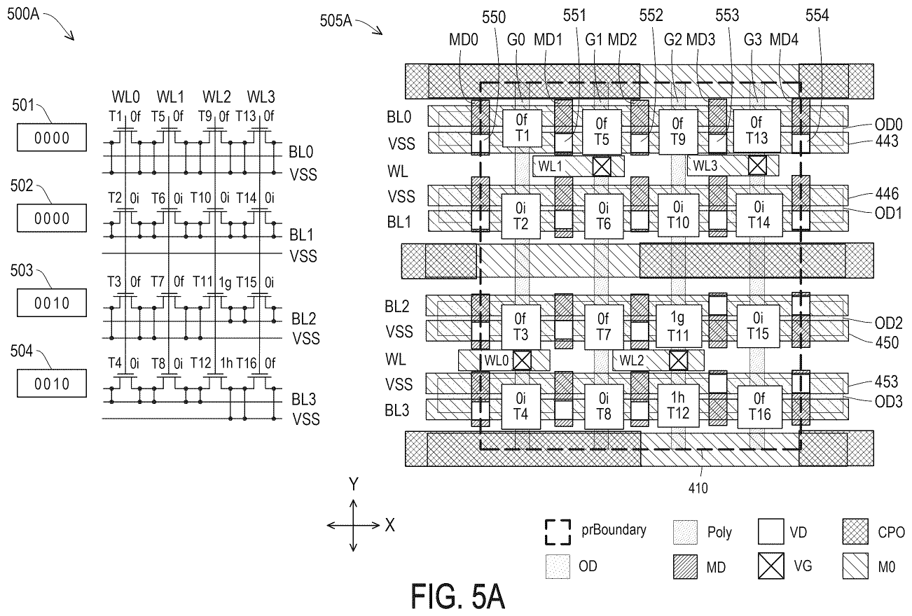

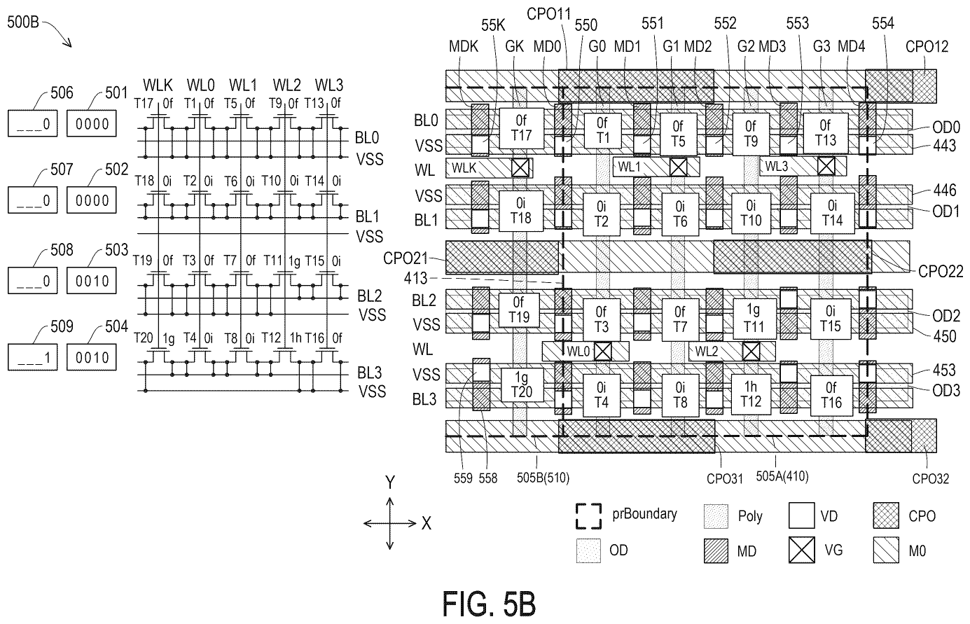

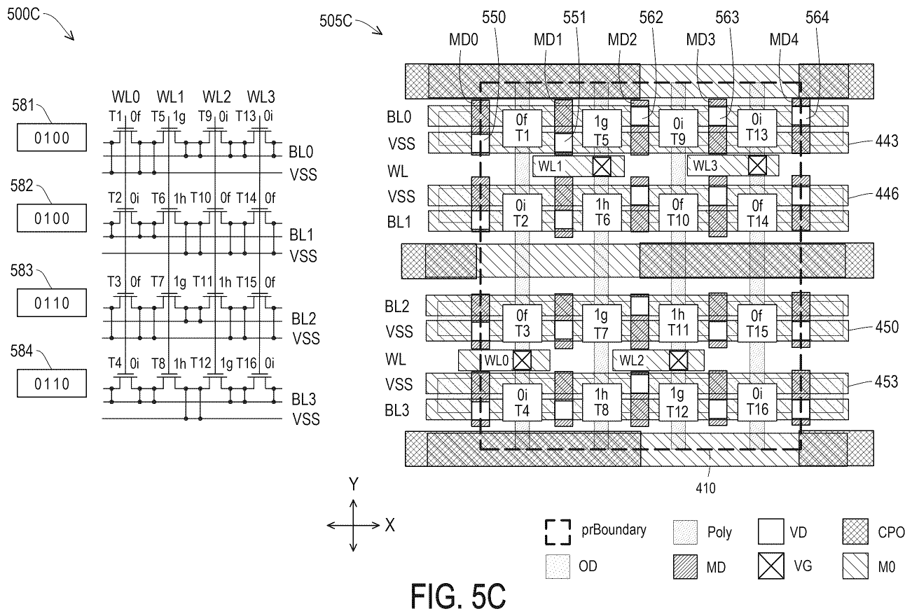

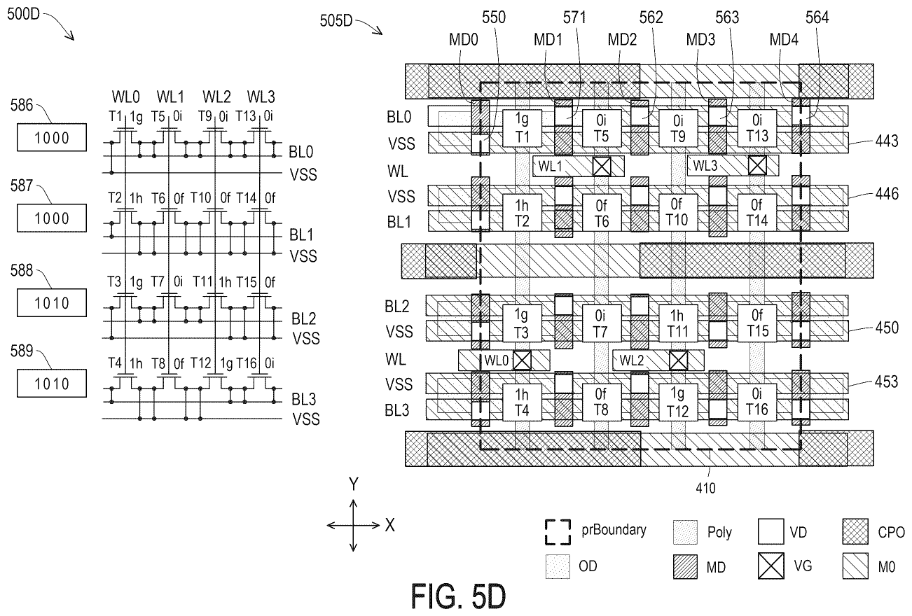

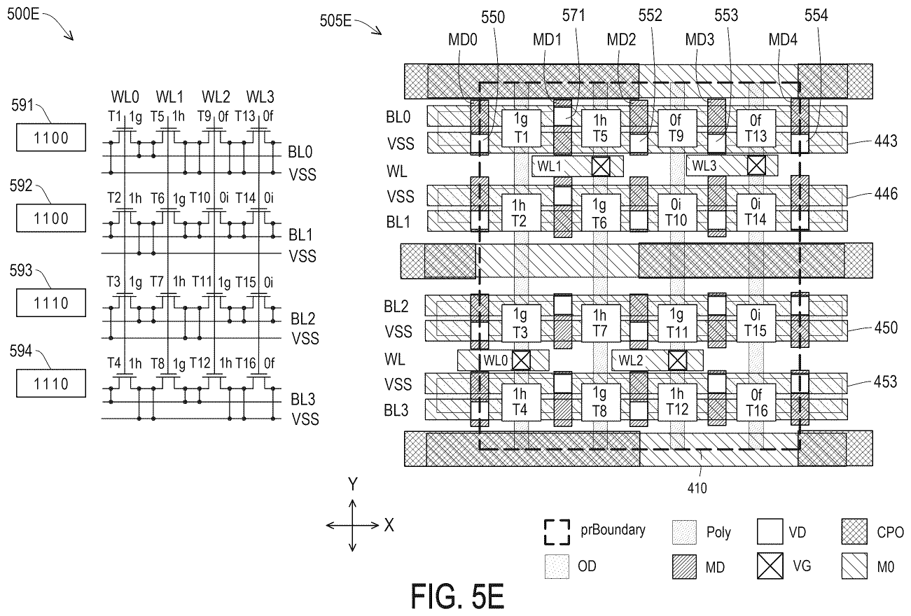

In some embodiments, an unprogrammed ROM array is programmed using a Code Pattern 1 using the configurations described with respect to FIGS. 2A-2D, without using the configurations described with respect to FIGS. 2E-2G. Non-limiting examples of ROM programming using the Code Pattern 1 are described with respect to FIGS. 5A-5E.

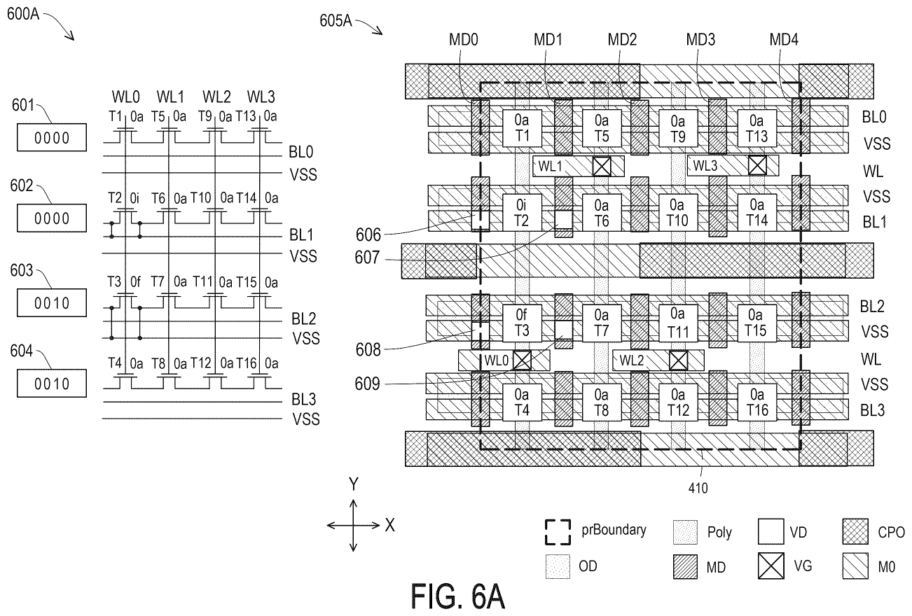

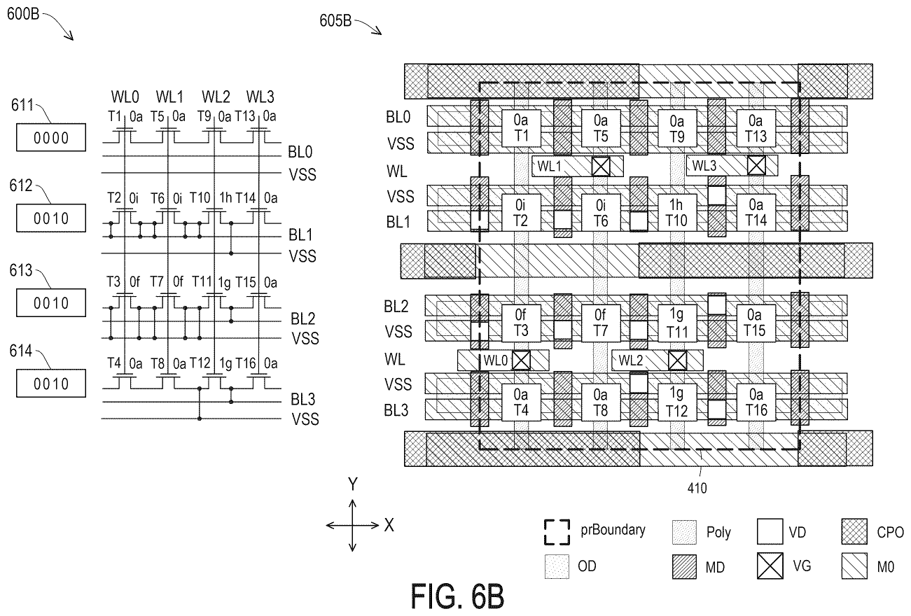

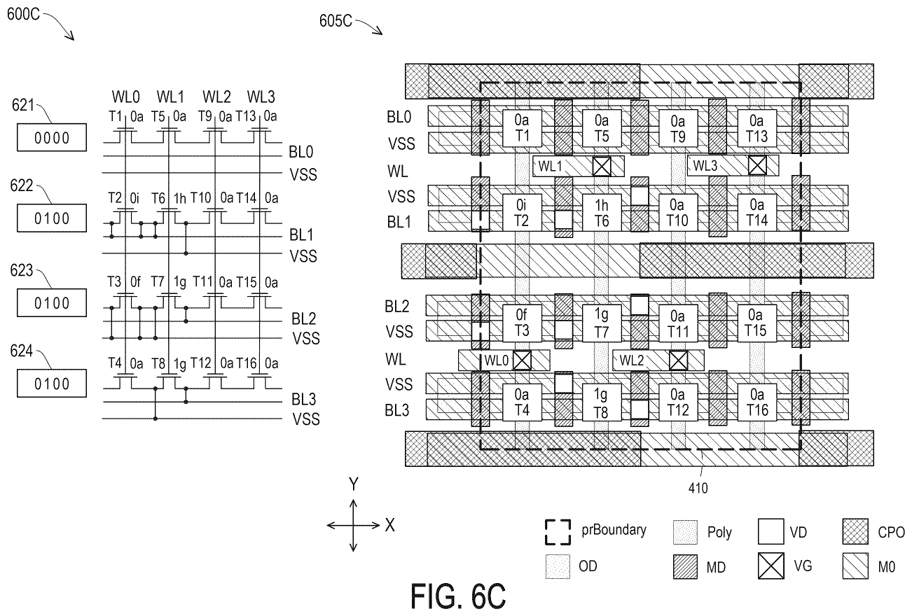

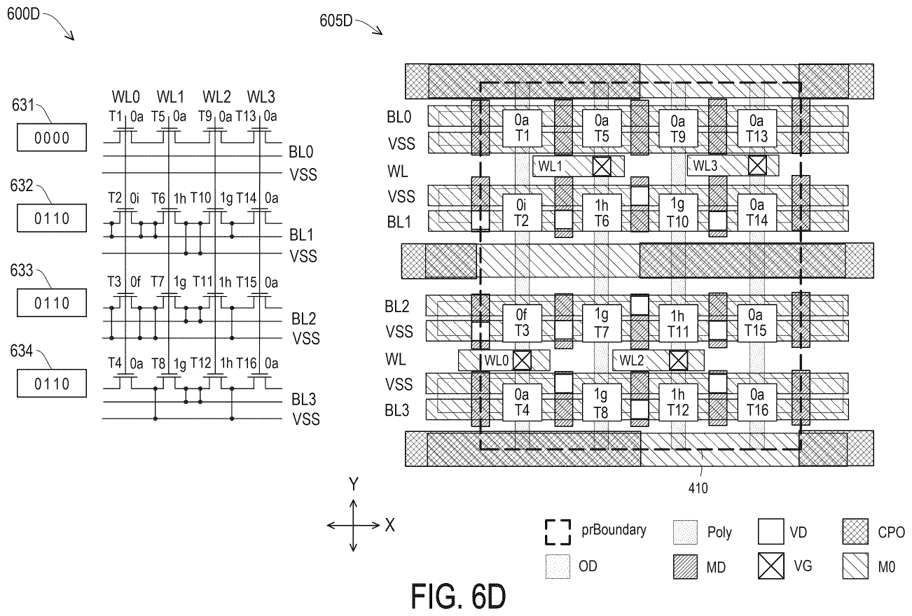

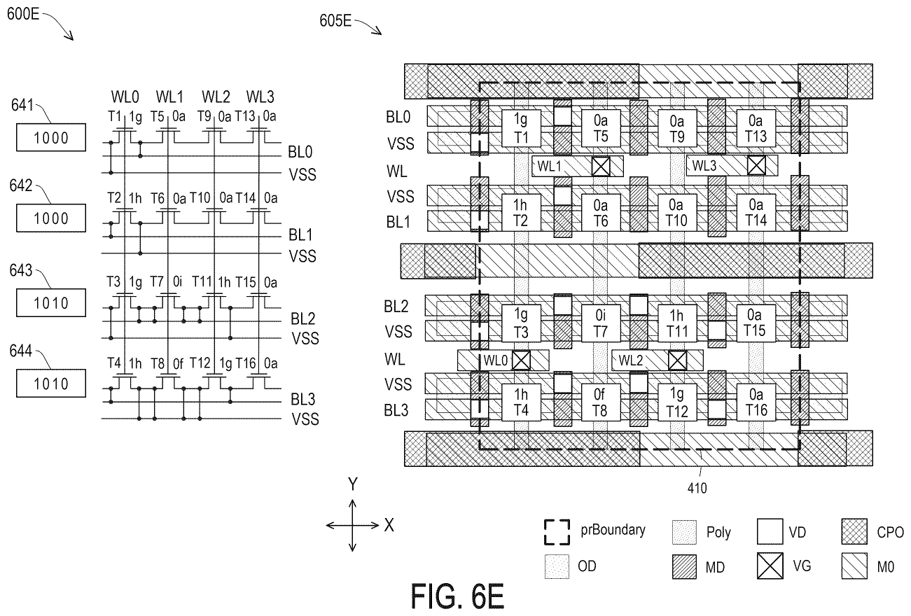

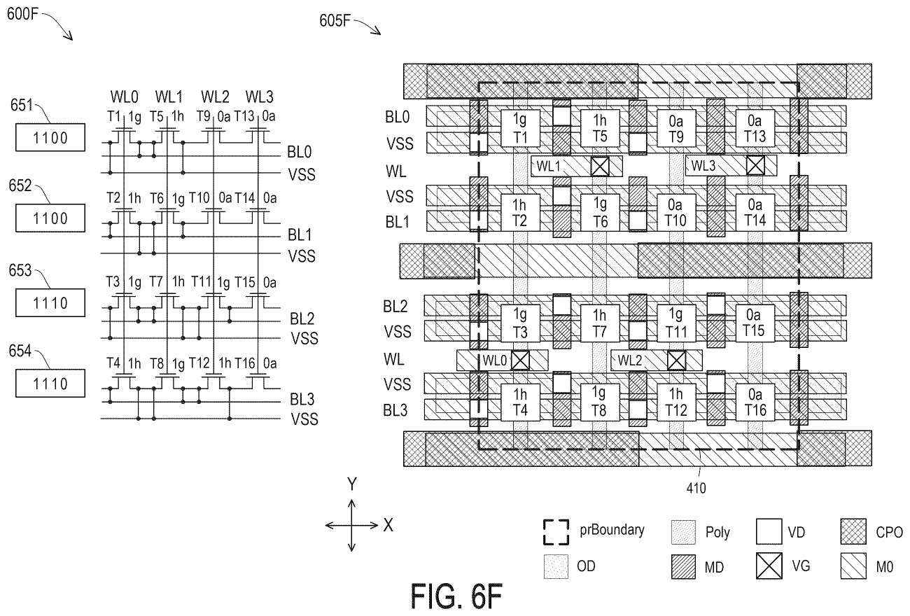

In some embodiments, an unprogrammed ROM array is programmed using a Code Pattern 2 using all configurations described with respect to FIGS. 2A-2G. Non-limiting examples of ROM programming using the Code Pattern 2 are described with respect to FIGS. 6A-6F.

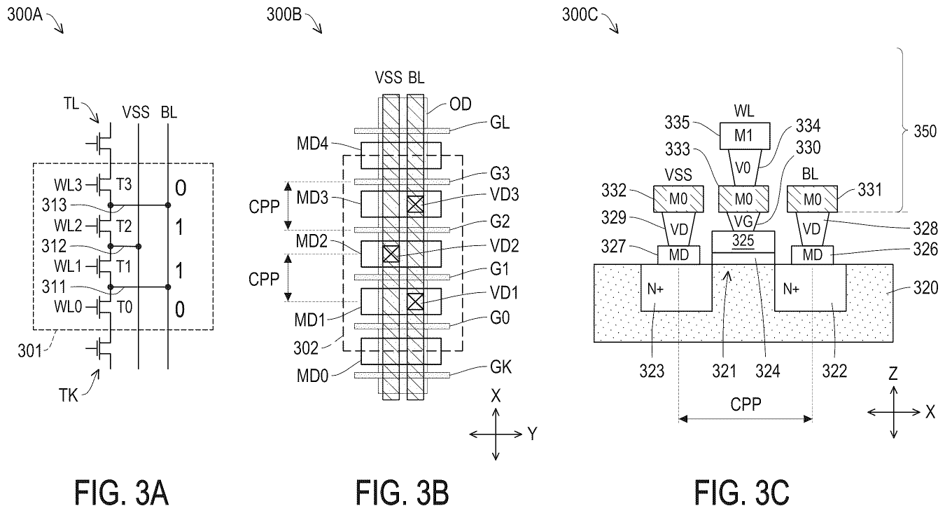

FIG. 3A is a schematic circuit diagram of a circuit region 301 of a memory device 300A, in accordance with some embodiments. In at least one embodiment, the memory device 300A corresponds to the memory device 100 and/or the circuit region 301 corresponds to a region in the memory array 101. For simplicity, corresponding components in FIGS. 1, 2A-2G, 3A are designated by the same reference numerals.

In FIG. 3A, the circuit region 301 comprises four consecutive bitcells each corresponding to a memory cell MC described with respect to FIG. 1 and/or one of the memory cells 200A-200G described with respect to FIGS. 2A-2G. The four bitcells correspondingly include transistors T0-T3. Gates of the transistors T0-T3 are electrically coupled correspondingly to word lines WL0-WL3. The transistors T0-T3 are serially coupled, such that a pair of directly adjacent transistors share a common source/drain. Two transistors are considered directly adjacent (or immediately adjacent) where there is no other transistor therebetween. In some embodiments, as described herein, two directly adjacent transistors have corresponding gates physically spaced from each other by 1 gate pitch (CPP). In the example configuration in FIG. 3A, the transistors TO, T1 are directly adjacent and share a common source/drain (not numbered) electrically coupled to an electrical connection 311, the transistors T1, T2 are directly adjacent and share a common source/drain (not numbered) electrically coupled to an electrical connection 312, and the transistors T2, T3 are directly adjacent and share a common source/drain (not numbered) electrically coupled to an electrical connection 313.

Another transistor TK outside the circuit region 301 is directly adjacent to the transistor TO and shares a common source/drain (not numbered) therewith. A further transistor TL outside the circuit region 301 is directly adjacent to the transistor T3 and shares a common source/drain (not numbered) therewith. In some embodiments, another instance of the circuit region 301 is arranged below (in FIG. 3A) and abuts the circuit region 301, and the transistor TK corresponds to the transistor T3 in such another instance of the circuit region 301 and has a gate electrically coupled to a word line (not shown). In some embodiments, a further instance of the circuit region 301 is arranged above (in FIG. 3A) and abuts the circuit region 301, and the transistor TL corresponds to the transistor TO in such further instance of the circuit region 301 and has a gate electrically coupled to a word line (not shown). In some embodiments, one of the transistors TK, TL is omitted, e.g., when the circuit region 301 is at an edge of a ROM array.

Each of the transistors T0-T3 (or the corresponding bitcell) is configured to store a predetermined datum or bit or logic value, in accordance with one of the configurations described with respect to FIGS. 2A-2G. For example, the transistor TO is configured to store logic “0”. Because one source/drain of the transistor TO is electrically coupled to the bit line BL by the electrical connection 311, the other source/drain of the transistor TO is either electrically coupled to the bit line BL in accordance with the OFF configuration 0i in FIG. 2D, or is electrically floating in accordance with the OFF configuration Oa in FIG. 2G. The transistor T1 is configured to store logic “1”, and has one source/drain electrically coupled to the bit line BL by the electrical connection 311, and the other source/drain electrically coupled to the VSS power rail by the electrical connection 312, in accordance with one of the ON configuration 1g in FIG. 2A and the ON configuration 1h in FIG. 2B. The transistor T2 is configured to store logic “1”, and has one source/drain electrically coupled to the VSS power rail by the electrical connection 312, and the other source/drain electrically coupled to the bit line BL by the electrical connection 313, in accordance with the other of the ON configuration 1g in FIG. 2A and the ON configuration 1h in FIG. 2B. The transistor T3 is configured to store logic “0”. Because one source/drain of the transistor T3 is electrically coupled to the bit line BL by the electrical connection 313, the other source/drain of the transistor T3 is either electrically coupled to the bit line BL in accordance with the OFF configuration 0i in FIG. 2D, or is electrically floating in accordance with the OFF configuration Oa in FIG. 2G. In some embodiments, each of the transistors TK, TL outside the circuit region 301 is also configured to store a logic value in accordance with one of the configurations described with respect to FIGS. 2A-2G.

FIG. 3B is a schematic view of a layout of a circuit region 302 of a memory device 300B, in accordance with some embodiments. In at least one embodiment, the memory device 300B corresponds to the memory device 300A and/or the circuit region 302 corresponds to the circuit region 301. For simplicity, corresponding components in FIGS. 1, 2A-2G, 3A-3B are designated by the same reference numerals.

As shown the layout in FIG. 3B, the memory device 300B comprises an active region OD extending along a first direction (e.g., an X axis), and a plurality of gates GK, G0-G3, GL extending across and over the active region OD, along a second direction (e.g., a Y axis) transverse to the first direction. The gates GK, G0-G3, GL correspondingly configure, together with the active region OD, transistors each of which is configured to store a datum. In some embodiments, the gates GK, G0-G3, GL in FIG. 3B correspond to the gates of the transistors TK, T0-T3, TL in FIG. 3A, and the transistors having the gates GK, G0-G3, GL in FIG. 3B correspond to the transistors TK, T0-T3, TL in FIG. 3A. The gates GK, G0-G3, GL are arranged along the X axis at a gate pitch (CPP) which is a distance along the X axis between center lines of directly adjacent gates, e.g., as illustrated for the gates G2, G3. Two gates are considered directly adjacent (or immediately adjacent) where there is no other gate therebetween.

The active region OD extends continuously along the X axis across and under more than four gates among the plurality of gates GK, G0-G3, GL. In the example configuration in FIG. 3B, the active region OD extends continuously across and under six gates GK, G0-G3, GL. In at least one embodiment, one of the gates GK, GL is omitted (e.g., when the circuit region 302 is at an edge of a ROM array) and the active region OD extends continuously across and under at least five gates. Other numbers (greater than 6) of gates under which the active region OD extends continuously are within the scopes of various embodiments. In some embodiments, the memory device 300B comprises multiple instances of the circuit region 302 arranged in abutment along the X axis. For example, another instance of the circuit region 302 is arranged below (in FIG. 3B) and abuts the circuit region 302, and/or a further instance of the circuit region 302 is arranged above (in FIG. 3B) and abuts the circuit region 302. In at least one embodiment, the active region OD extends continuously across and under the gates of multiple instances of the circuit region 302 arranged in abutment along the X axis. In some embodiments, all gates, across and under which the active region OD continuously extends, belong to transistors configured to store data, such as the transistors TK, T0-T3, TL described with respect to FIG. 3A and/or the transistors T described with respect to FIGS. 2A-2G.

The active region OD extends continuously along the X axis across and under more than four gates of transistors configured to store data, without being interrupted or discontinued by an isolation structure. In some embodiments, the memory device 300B is free of an isolation structure that divides the active region OD into electrically isolated portions. This is a distinction from other approaches which include isolation structures inside and/or on edges of a circuit region. For example, in accordance with the other approaches, there would be isolation structures under the gates GL and GK and elongated along the Y axis to divide the active region OD into three electrically isolated portions. Alternatively, or additionally, in accordance with the other approaches, the gates GL and GK would be dummy gates which include non-conductive materials and/or form no transistors configured to store data. For example, in accordance with the other approaches, the gates GL and GK would be dummy gates which are not electrically coupled to a word line. In contrast, in one or more embodiments, each of the multiple gates, which the active region OD extends continuously across and under, is electrically coupled to a word line and the transistor formed by such a gate and the active region OD is configured to store a datum. Compared to the other approaches in which isolation structures dividing an active region into electrically isolated portions exist, a size of the memory device 300B in which the active region OD extends continuously is advantageously reduced.

The memory device 300B further comprises contact structures MD0-MD4 correspondingly over source/drains of the transistors configured by the gates GK, G0-G3, GL with the active region OD. For simplicity, not all contact structures are illustrated in FIG. 3B. The contact structures MD0-MD4 are arranged along the X axis at the gate pitch (CPP) which is a distance along the X axis between center lines of directly adjacent contact structures, e.g., as illustrated for the contact structures MD1, MD2. Two contact structures are considered directly adjacent (or immediately adjacent) where there is no other contact structure therebetween. The contact structures MD0, MD4 are arranged on edges of the circuit region 302 and are shared with other instances of the circuit region 302 arranged in abutment with the circuit region 302. This is a further distinction from the other approaches in which isolation structures and/or dummy gates are arranged on edges of a circuit region.

The memory device 300B further comprises a bit line BL and a VSS power rail overlapping the active region OD, and extending continuously along the X axis across multiple gates. In the example configuration in FIG. 3B, the bit line BL and the VSS power rail are conductive patterns in a same metal layer over the contact structures MD0-MD4 and the gates GK, G0-G3, GL. In some embodiments, the bit line BL and VSS power rail extend continuously across as many gates as the active region OD.

The memory device 300B further comprises vias VD1-VD3 each electrically coupling a corresponding one of the contact structures MD0-MD4 to the bit line BL or the VSS power rail, to program or configure the corresponding transistors to store predetermined data. In at least one embodiment, the vias VD1-VD3 correspond to the electrical connections 311-313.

In at least one embodiment, because the size of the memory device 300B in which the active region OD extends continuously is advantageously reduced, a length of the bit line BL along the X axis is also advantageously reduced, compared to the other approaches in which isolation structures dividing an active region into electrically isolated portions exist. In at least one embodiment, the reduced length of the bit line BL provides one or more further advantages including, but not limited to, reduced parasitic capacitance, lower requirements for driving strength and/or size of a bit line driving circuit, or the like.

FIG. 3C is a schematic cross-sectional view of a circuit region of a memory device 300C, in accordance with some embodiments. In at least one embodiment, the memory device 300C corresponds to one or more of the memory devices 100, 300A, 300B. For simplicity, corresponding components in FIGS. 1, 2A-2G, 3A-3C are designated by the same reference numerals.

The memory device 300C comprises a substrate 320, and at least one transistor 321 over the substrate 320. In at least one embodiment, the transistor 321 corresponds to one or more of the memory cells MC in the memory device 100, the memory cells 200A-200G, the transistors TK, T0-T3, TL, and the transistors having the gates GK, G0-G3, GL.

In some embodiments, the substrate 320 is a semiconductor substrate. N-type and P-type dopants are added to the substrate to correspondingly form N wells 322, 323, and P wells (not shown). In some embodiments, isolation structures are formed between adjacent P wells and N wells. For simplicity, several features such as P wells and isolation structures are omitted from FIG. 3C.

The transistor 321 comprises a gate stack and source/drains. The N wells 322, 323 define the source/drains of the transistor 321. A section of the substrate 320, or a P well (not shown), between the source/drains 322, 323 corresponds to a channel of the transistor 321. The channel and the source/drains 322, 323 together correspond to an active region, such as the active region OD described with respect to FIG. 3B. The gate stack of the transistor 321 comprises a gate dielectric layer 324, and a gate 325. In at least one embodiment, the transistor 321 comprises multiple gate dielectric layers. Example materials of the gate dielectric layer or layers include HfO₂, ZrO₂, or the like. Example materials of the gate 325 include polysilicon (poly), metal, or the like. The described configuration of the transistor 321 is an example. Various other transistor configurations are within the scopes of various embodiments.

The memory device 300C further comprises conductive features configured to electrically couple the transistor 321 to other circuitry in the memory device 300C. The conductive features comprise source/drain (metal-to-device, or MD) contact structures 326, 327 correspondingly over and in electrical contact with the source/drains 322, 323. The conductive features further comprise various vias. For example, a via-to-gate (VG) via 330 is over and in electrical contact with the gate 325. Via-to-device (VD) vias 328, 329 are correspondingly over and in electrical contact with the MD contact structures 326, 327. The VG via 330 and/or VD vias 328, 329 are configured to couple the transistor 321 to various patterns in an M0 layer of a redistribution structure 350, as described herein.

The redistribution structure 350 comprises a plurality of metal layers M0, M1, . . . and a plurality of via layers V0, V1, . . . arranged alternatingly in a thickness direction, i.e., along a Z axis, of the substrate 320. The redistribution structure 350 further comprises various interlayer dielectric (ILD) layers (not shown) in which the metal layers and via layers are embedded. The M0 layer, i.e., metal-zero (M0) layer, is the lowermost metal layer immediately over and in electrical contact with the VD and VG vias, and is schematically illustrated in the drawings with the label “M0.” The M1 layer is the metal layer immediately over the M0 layer, and is schematically illustrated in the drawings with the label “M1.” The redistribution structure 350 further comprises other metal layers sequentially stacked over the M1 layer. The redistribution structure 350 also comprises via layers arranged between and electrically couple successive metal layers. A via layer Vn is arranged between and electrically couple the Mn layer and the Mn+1 layer, where n is an integer form zero and up. For example, a via-zero (V0) layer is the lowermost via layer which is arranged between and electrically couple the M0 layer and the M1 layer, and is schematically illustrated in the drawings with the label “V0.” The metal layers and via layers of the redistribution structure 350 are configured to form interconnects that electrically couple various elements or circuits of the memory device 300C with each other, and with external circuitry.

In the example configuration in FIG. 3C, the M0 layer comprises M0 conductive patterns 331, 332, 333 correspondingly over and in electrical contact with the VD via 328, the VD via 329, the VG via 330. In at least one embodiment, the M0 conductive pattern 331 corresponds to one of the bit line BL and VSS power rail, whereas the M0 conductive pattern 332 corresponds to the other of the bit line BL and VSS power rail. For example, the M0 conductive pattern 331 corresponds to the bit line BL, and the M0 conductive pattern 332 corresponds to the VSS power rail. The M0 conductive patterns 331, 332 are elongated along the X axis, as described with respect to FIG. 3B. The M0 conductive pattern 333 corresponds to a word line pattern which is electrically coupled, by a V0 via 334, to an M1 conductive pattern 335 in the M1 layer. The M1 conductive pattern 335 corresponds to a word line and is elongated along the Y axis.

The configuration in FIG. 3C where the MD contact structures 326, 327 are correspondingly coupled to the bit line BL (M0 conductive pattern 331) and the VSS power rail (M0 conductive pattern 332) is an example and corresponds to, e.g., the ON configuration 1g in FIG. 2A.

When the transistor 321 is configured to have the ON configuration 1h in FIG. 2B, the MD contact structures 326, 327 are correspondingly coupled to the VSS power rail (M0 conductive pattern 332) and the bit line BL (M0 conductive pattern 331).

When the transistor 321 is configured to have the OFF configuration 0f in FIG. 2C, the MD contact structures 326, 327 are both coupled to the VSS power rail (M0 conductive pattern 332).

When the transistor 321 is configured to have the OFF configuration 0i in FIG. 2D, the MD contact structures 326, 327 are both coupled to the bit line BL (M0 conductive pattern 331).

When the transistor 321 is configured to have the OFF configuration Oa in FIG. 2E, the MD contact structures 326, 327 are not coupled to the VSS power rail (M0 conductive pattern 332) and the bit line BL (M0 conductive pattern 331). For example, both of the VD vias 328, 329 are omitted.

When the transistor 321 is configured to have the OFF configuration Oa in FIG. 2F, the MD contact structure 326 is not coupled to the bit line BL (M0 conductive pattern 331). For example, the VD via 328 is omitted.

When the transistor 321 is configured to have the OFF configuration Oa in FIG. 2G, the MD contact structure 327 is not coupled to the VSS power rail (M0 conductive pattern 332). For example, the VD via 329 is omitted. One or more advantages described herein are achievable by the memory device 300C, in accordance with some embodiments.

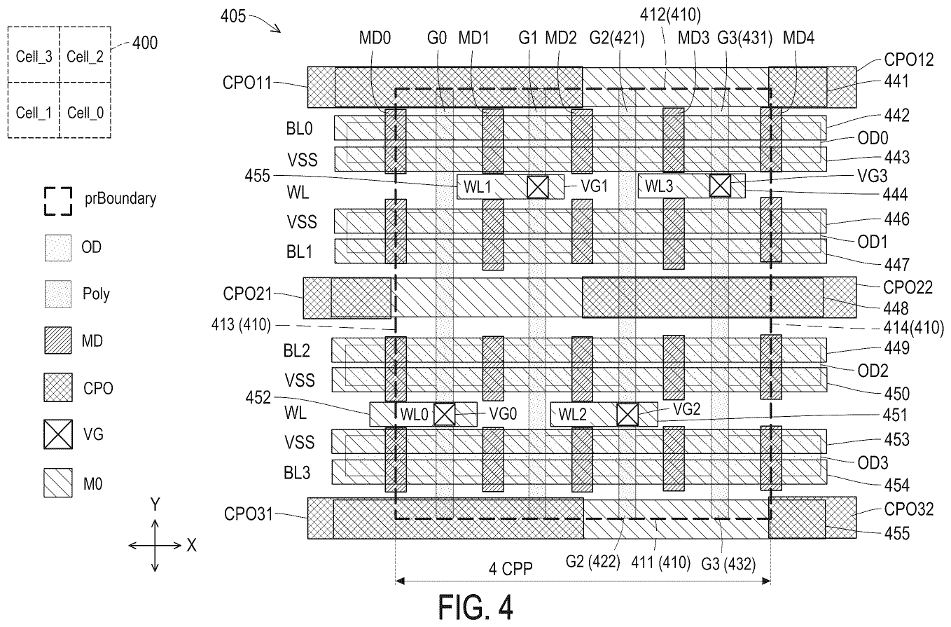

FIG. 4 is a schematic view of a layout of a circuit region of a memory device 400, in accordance with some embodiments. In some embodiments, the memory device 400 corresponds to one or more of the memory devices 100, 300A, 300B, 300C. For simplicity, corresponding components in FIGS. 1, 2A-2G, 3A-3C, 4 are designated by the same reference numerals.

The memory device 400 comprises a plurality of instances of a circuit region, and the instances are arranged in abutment with each other long the X axis and Y axis. Some instances of the circuit region are illustrated in FIG. 4 as Cell_0, Cell_1, Cell_2, Cell_3, for example. Other instances of the circuit region are omitted in FIG. 4 for simplicity. Cell_0, Cell_1, Cell_2, Cell_3 are arranged in abutment with each other along their corresponding boundaries as illustrated in FIG. 4. Each of Cell_0, Cell_1, Cell_2, Cell_3 corresponds to a ROM cell 405 having a layout illustrated in FIG. 4. In at least one embodiment, the ROM cell 405 is stored as a standard cell in a standard cell library on a non-transitory computer-readable medium. In the example configuration in FIG. 4, the ROM cell 405 is a 4×4 ROM cell including 16 bitcells arranged in four rows along the X axis and four columns along the Y axis. Other sizes and/or dimensions of a ROM cell are within the scopes of various embodiments.

The ROM cell 405 comprises a boundary 410 (i.e., a cell boundary) by which multiple instances of the ROM cell 405 are placed in abutment as described herein. For example, the boundary 410 corresponds to the boundary of each of Cell_0, Cell_1, Cell_2, Cell_3. The boundary 410 comprises edges 411, 412, 413, 414. The edges 411, 412 are elongated along the X axis, and the edges 413, 414 are elongated along the Y axis. In some embodiments, the X axis is an example of one of a first direction and a second direction, and the Y axis is an example of the other of the first direction and the second direction. The edges 411, 412, 413, 414 are connected together to form the closed boundary 410. In a place-and-route operation (also referred to as “automated placement and routing (APR)”) described herein, multiple instances of the ROM cell 405 are placed in abutment with each other at their respective boundaries in a layout of the memory device 400 or a ROM array thereof. The rectangular or square shape of the boundary 410 is an example.

The ROM cell 405 comprises active regions OD0-OD3, and gates G0-G3. The active regions OD0-OD3 are spaced from each other along the Y axis. The active regions OD0-OD3 extend continuously along the X axis within the boundary 410 and also beyond the boundary 410 into further instances of the ROM cell 405 arranged in abutment along the X axis. For example, when the ROM cell 405 corresponds to Cell_0, the active regions OD0-OD3 extend continuously through at least Cell_0, Cell_1. The ROM cell 405 is free of isolation structures dividing any of the active regions OD0-OD3 into electrically isolated portions. Active regions are sometimes referred to as oxide-definition (OD) regions, and are schematically illustrated in the drawings with the label “OD.” In the example configuration in FIG. 4, all of the active regions OD0-OD3 are N-type, or NMOS, active regions configured to form N-type, or NMOS, transistors. In at least one embodiment, each of the active regions OD0-OD3 corresponds to the active region OD described with respect to FIG. 3B.

The gates G0-G3 extend across the active regions OD0-OD3 along the Y axis. The gates G0-G3 are spaced from each other along the X axis by a gate pitch (CPP) as described herein. Each of the gates G0-G3 is a conductive gate that includes a conductive material, such as, polysilicon, and is schematically illustrated in the drawings with the label “PO.” Other conductive materials for the gates, such as metals, are within the scope of various embodiments. The gates G0-G3 configure, together with each of the active regions OD0-OD3, a string of serially coupled transistors, as described with respect to FIG. 3B. All of the gates G0-G3 are functional gates which, together with an active region among the active regions OD0-OD3, configure transistors configured to store data. The transistors in the ROM cell 405 correspond to transistors T1-T16 described with respect to FIG. 5A. The ROM cell 405 is free of dummy gates which include non-conductive materials and/or form no transistors configured to store data.

The ROM cell 405 further comprises cut-gate (or cut-poly) regions CPO11, CPO12, CPO21, CPO22, CPO31, CPO32 extending along the X axis across the gates G0-G3. The cut-gate regions are schematically illustrated in the drawings with the label “CPO.” A cut-gate region corresponds to a region where gates are not to be formed.

For example, a length of the gates G0, G1 along the Y axis is defined by the cut-gate regions CPO11, CPO31 which correspondingly define opposite ends of each of the gates G0, G1. The cut-gate regions CPO21, CPO22 are aligned, and spaced from each other along the X axis. The gates G0, G1 extend continuously along the Y axis through the space between the cut-gate regions CPO21, CPO22.

The cut-gate region CPO22 cuts or separates the gate G2 into two physically disconnected gate portions 421, 422, and also cuts or separates the gate G3 into two physically disconnected gate portions 431, 432. The physically disconnected gate portions 421, 422 are nevertheless electrically coupled with each other by a word line WL2 in, e.g., the M1 layer, and the physically disconnected gate portions 431, 432 are nevertheless electrically coupled with each other by a word line WL3 in, e.g., the M1 layer.

The cut-gate regions CPO11, CPO12 are aligned, and spaced from each other along the X axis. In some embodiments, center lines of the cut-gate regions CPO11, CPO12 coincide with the edge 412 of the boundary 410. The gate portions 421, 431 of the corresponding gates G2, G3 extend continuously along the Y axis through the space between the cut-gate regions CPO11, CPO12 into another instance of the ROM cell 405 abutting the ROM cell 405 along the edge 412. For example, when the ROM cell 405 corresponds to Cell_0, the gate portions 421, 431 of the corresponding gates G2, G3 extend continuously from Cell_0 into Cell_2. A length of the gate portions 421, 431 of the corresponding gates G2, G3, including the parts in both Cell_0 and Cell_2, is the same or substantially the same as the length of the gates G0, G1.

The cut-gate regions CPO31, CPO32 are aligned, and spaced from each other along the X axis. In some embodiments, center lines of the cut-gate regions CPO31, CPO32 coincide with the edge 411 of the boundary 410. The gate portions 422, 432 of the corresponding gates G2, G3 extend continuously along the Y axis through the space between the cut-gate regions CPO31, CPO32 into another instance of the ROM cell 405 abutting the ROM cell 405 along the edge 411. For example, when the ROM cell 405 corresponds to Cell_2, the gate portions 422, 432 of the corresponding gates G2, G3 extend continuously from Cell_2 into Cell_0. A length of the gate portions 422, 432 of the corresponding gates G2, G3, including the parts in both Cell_0 and Cell_2, is the same or substantially the same as the length of the gates G0, G1. In some embodiments, the described staggering arrangement of the cut-gate regions results in gate portions of the same or substantially the same lengths, and/or reduce the Poly Extension Effect (PXE).

The ROM cell 405 further comprises MD contact structures. MD contact structures over the active region OD0 are designated in FIG. 4 as MD0-MD4, whereas MD contact structures over the active regions OD1-OD3 are not designated for simplicity. In at least one embodiment, the MD contact structures over each of the active regions OD0-OD3 correspond to the contact structures MD0-MD4 described with respect to FIG. 3B. The MD contact structures are spaced from each other along the X axis by the gate pitch (CPP), and are alternatingly arranged with respect to the gates G0-G3 along the X axis. MD contact structures are schematically illustrated in the drawings with the label “MD.”

A first set of MD contact structures (and the underlying source/drains) including the MD contact structure MD0 is arranged along the edge 413 of the boundary 410, and is configured to be shared with another instance of the ROM cell 405 abutting the ROM cell 405 along the edge 413. For example, when the ROM cell 405 corresponds to Cell_0, the first set of MD contact structures along the edge 413 is shared by Cell_0 and Cell_1. In other words, Cell_0 and Cell_1 directly abut each other without a gate or a dummy gate therebetween. In at least one embodiment, the MD contact structures in the first set has center lines coinciding with the edge 413. A second set of MD contact structures (and the underlying source/drains) including the MD contact structure MD4 is arranged along the edge 414 of the boundary 410, and is configured to be shared with another instance of the ROM cell 405 abutting the ROM cell 405 along the edge 414. In at least one embodiment, the MD contact structures in the second set have center lines coinciding with the edge 414.

In the example configuration in FIG. 4, a width of the ROM cell 405 along the X axis is 4 CPPs. This width is advantageously reduced compared to 4×4 ROM cells in accordance with the other approaches, and is achievable by configuring the active regions OD0-OD3 to be continuous without being interrupted or disconnected by one or more isolation structures inside the ROM cell 405 and/or on the boundary 410. A 4×4 ROM cell in accordance with another approach includes isolation structures on active regions along Y-axis-elongated edges, and has a width of 5 CPPs along the X axis. A 4×4 ROM cell in accordance with yet another approach includes isolation structures on active regions not only along Y-axis-elongated edges but also inside the ROM cell, and has a width of 6 CPPs along the X axis. A 4-CPP 4×4 ROM cell in accordance with one or more embodiments achieves an area reduction of about 16.7% compared to the described 5-CPP 4×4 ROM cell, or about 33.3% compared to the described 6-CPP 4×4 ROM cell of the other approaches. The reduced width of the ROM cell in accordance with some embodiments further advantageously reduces the bit line length of various bit lines, as described herein.

The ROM cell 405 further comprises via-to-gate vias VG0-VG3 correspondingly over and in electrical contact with the corresponding gates G0-G3. The via-to-gate vias are schematically illustrated in the drawings with the label “VG.”

The ROM cell 405 further comprises, in an M0 layer, M0 conductive patterns 441-455. The M0 conductive patterns 442, 447, 449, 454 correspondingly configure a plurality of bit lines BL0-BL3, and the M0 conductive patterns 443, 446, 450, 453 correspondingly configure a plurality of VSS power rails. The bit lines BL0-BL3 and the VSS power rails extend continuously along the X axis through multiple abutting instances of the ROM cell 405. Each pair of a bit line and a corresponding VSS power rail extend over a corresponding active region. For example, the bit line BL0 and the corresponding VSS power rail (M0 conductive pattern 443) extend over the active region OD0.

The M0 conductive patterns 452, 445, 451, 444 correspondingly configure word line patterns. The word line patterns 444, 445 are aligned along the X axis and are arranged on a same M0 track. The word line patterns 451, 452 are aligned along the X axis and are arranged on a same M0 track. The word line patterns 452, 445, 451, 444 are correspondingly over and in electrical contact with the VG vias VG0-VG3 to be whereby electrically coupled correspondingly to the gates G0-G3. The word line patterns 452, 445, 451, 444 are electrically coupled, through corresponding V0 vias (not shown), to corresponding word lines WL0-WL3 (not shown) in the M1 layer, in a manner similar to that described with respect to FIG. 3C. In an example when the ROM cell 405 corresponds to Cell_0, the word line WL0 in the M1 layer extends continuously along the Y axis over the word line pattern 452 and a similar word line pattern in Cell_2, and is electrically coupled to the word line pattern 452 and the similar word line pattern in Cell_2 by corresponding V0 vias. As a result, all transistors configured by the gate G0 in Cell_0 and Cell_2 are electrically coupled to the word line WL0.

In the example configuration in FIG. 4, the ROM cell 405 does not yet include via-to-device (VD) vias correspondingly over and in electrical contact with one or more MD contact structures. This is because the ROM cell 405, in accordance with some embodiments, is a blank or unprogrammed ROM cell. In some embodiments, at the design stage, a blank or unprogrammed ROM array corresponding to the memory array 101 is developed, by arranging (e.g., in an APR operation) a plurality of instances of the ROM cell 405 in abutment with each other as exemplified by Cell_0, Cell_1, Cell_2, Cell_3 in FIG. 4. In a subsequent programming stage, the unprogrammed ROM array is programmed in accordance with predetermined data to be stored in the ROM array, by generating a set of VD vias to configure each individual bitcell in the ROM array to store logic “0” or logic “1”, as described with respect to FIGS. 2A-2G, 3A-3C. Specific, non-limiting examples of ROM programming are further described with respect to FIGS. 5A-5E, 6A-6F.

FIGS. 5A-5E each include a schematic circuit diagram and a schematic view of a layout of a circuit region of a memory device, in accordance with some embodiments. FIGS. 5A-5E show non-limiting examples of ROM programming using the Code Pattern 1, i.e., using the configurations described with respect to FIGS. 2A-2D, without using the configurations described with respect to FIGS. 2E-2G. For simplicity, corresponding components in FIGS. 1, 2A-2G, 3A-3C, 4, 5A-5E are designated by the same reference numerals.

FIG. 5A includes a schematic circuit diagram of a circuit region 500A, and a schematic view of a layout of a ROM cell 505A corresponding to the circuit region 500A. The ROM cell 505A is a programmed instance of the unprogrammed ROM cell 405. The ROM cell 505A comprises transistors T1-T16, among which the transistors T1, T5, T9, T13 are configured correspondingly by the gates G0-G3 with the active region OD0, the transistors T2, T6, T10, T14 are configured correspondingly by the gates G0-G3 with the active region OD1, the transistors T3, T7, T11, T15 are configured correspondingly by the gates G0-G3 with the active region OD2, and the transistors T4, T8, T12, T16 are configured correspondingly by the gates G0-G3 with the active region OD3.

The ROM cell 505A is programmed so that the transistors T1, T5, T9, T13 store data or code 501, the transistors T2, T6, T10, T14 store data or code 502, the transistors T3, T7, T11, T15 store data or code 503, and the transistors T4, T8, T12, T16 store data or code 504. In each of the codes 501-504, “0” indicates logic “0” and “1” indicates logic “1”. For example, the code 501 is “0000” and corresponds to the transistors T1, T5, T9, T13 all storing logic “0”. For a further example, the code 503 is “0010” and corresponds to the transistor T3 storing logic “0”, the transistor T7 storing logic “0”, the transistor T11 storing logic “1”, and the transistor T15 storing logic “0”. Compared to the ROM cell 405, the ROM cell 505A further comprises VD vias each electrically coupling a source/drain in an active region among the active regions OD0-OD3 to the corresponding bit line or the corresponding power rail over the active region, in accordance with the data of codes 501-504 to be stored. VD vias 550-554 are designated in FIG. 5A, whereas other VD vias are not designated for simplicity. In some embodiments, each of the codes 501-504 is programmed into the ROM cell 505A independently from the other codes. In an example ROM programming operation, a code among the codes 501-504 is programed sequentially, e.g., from left to right or from right to left. For example, the code 501 is programmed sequentially from right to left, starting from the transistor T13.

The transistor T13 is programed to store logic “0” which, in accordance with the Code Pattern 1, corresponds to either the OFF configuration 0f in FIG. 2C or the OFF configuration 0i in FIG. 2D. In at least one embodiment, the selection between the OFF configuration 0f and OFF configuration 0i is made depending on a further transistor (not shown) which is on the bit line BL0, directly adjacent to the transistor T13 on the right side, and shares a common source/drain (under the MD contact structure MD4) with the transistor T13. Such further transistor has been programed before the transistor T13. If the programed further transistor has the common source/drain with the transistor T13 coupled to the VSS power rail, the OFF configuration 0f is selected for the transistor T13. If the programed further transistor has the common source/drain with the transistor T13 coupled to the bit line BL0, the OFF configuration 0i is selected for the transistor T13. In the example configuration in FIG. 5A, the transistor T13 is programed to have the OFF configuration 0f. For this purpose, VD vias 553, 554 are generated (e.g., by an EDA tool performing the APR operation) to correspondingly couple both source/drains of the transistor T13 to the VSS power rail 443 in the ROM cell 505A. In at least one embodiment, the VD via 554 has already been generated when the further transistor on the right side of the transistor T13 is programed, and the VD via 553 is generated when the transistor T13 is programed.

Next, the transistor T9 is programed to store logic “0”. Because the common source/drain (under the MD contact structure MD3) of the transistor T9 and the transistor T13 is already coupled to the VSS power rail 443 by the VD via 553, the OFF configuration 0f is selected for programming the transistor T9. For this purpose, a VD via 552 is generated to couple the other source/drain (under the MD contact structure MD2) of the transistor T9 to the VSS power rail 443. Similarly, the transistor T5 is programed to store logic “0” by generating a VD via 551 to couple the MD contact structure MD1 to the VSS power rail 443, and the transistor T1 is programed to store logic “0” by generating a VD via 550 to couple the MD contact structure MD0 to the VSS power rail 443.

The code 502, i.e., “0000”, is programed into the transistors T2, T6, T10, T14, starting from the transistor T14 which is programed to have the OFF configuration 0i. As a result, both source/drains of the transistor T14 are coupled to the bit line BL1. Because the common source/drain of the transistor T10 and the transistor T14 is coupled to the bit line BL1 when the transistor T14 is programed, the other source/drain of the transistor T10 is also coupled to the bit line BL1 so as to program logic “0” into the transistor T10 in accordance with the OFF configuration 0i. Similarly, the transistor T6 is programmed to have the OFF configuration 0i based on the programed configuration of the transistor T10, and then the transistor T2 is programmed to have the OFF configuration 0i based on the programed configuration of the transistor T6. The APR tool is configured to generate a set of VD vias (not numbered) corresponding to the OFF configuration 0i at all of the transistors T2, T6, T10, T14, as illustrated in the ROM cell 505A.

The code 503, i.e., “0010”, is programed into the transistors T3, T7, T11, T15, starting from the transistor T15 which is programed to have the OFF configuration 0i. As a result, both source/drains of the transistor T15 are coupled to the bit line BL2. Because the common source/drain of the transistor T11 and the transistor T15 is coupled to the bit line BL2 when the transistor T15 is programed, the other source/drain of the transistor T11 is coupled to the VSS power rail so as to program logic “1” into the transistor T11 in accordance with the ON configuration 1g in FIG. 2A. Because the common source/drain of the transistor T7 and the transistor T11 is coupled to the VSS power rail when the transistor T11 is programed, the other source/drain of the transistor T7 is also coupled to the VSS power rail so as to program logic “0” into the transistor T7 in accordance with the OFF configuration 0f. Similarly, the transistor T3 is programmed to have the OFF configuration 0f based on the programed configuration of the transistor T7. The APR tool is configured to generate a set of VD vias (not numbered) corresponding to the programed configurations of the transistors T3, T7, T11, T15, as illustrated in the ROM cell 505A.

The code 504, i.e., “0010”, is programed into the transistors T4, T8, T12, T16, starting from the transistor T16 which is programed to have the OFF configuration 0f. As a result, both source/drains of the transistor T16 are coupled to the VSS power rail. Because the common source/drain of the transistor T12 and the transistor T16 is coupled to the VSS power rail when the transistor T16 is programed, the other source/drain of the transistor T12 is coupled to the bit line BL3 so as to program logic “1” into the transistor T12 in accordance with the ON configuration 1h in FIG. 2B. Because the common source/drain of the transistor T8 and the transistor T12 is coupled to the bit line BL3 when the transistor T12 is programed, the other source/drain of the transistor T8 is also coupled to the bit line BL3 so as to program logic “0” into the transistor T8 in accordance with the OFF configuration 0i. Similarly, the transistor T4 is programmed to have the OFF configuration 0i based on the programed configuration of the transistor T8. The APR tool is configured to generate a set of VD vias (not numbered) corresponding to the programed configurations of the transistors T4, T8, T12, T16, as illustrated in the ROM cell 505A.

In FIG. 5A, the programed configurations of the transistors T1, T5, T9, T13 include an example of programming data “0000” by configuring all of the transistors T1, T5, T9, T13 to have the OFF configuration 0f, whereas the programed configurations of the transistors T2, T6, T10, T14 include another example of programming the same data “0000” by configuring all of the transistors T2, T6, T10, T14 to have the OFF configuration 0i. In at least one embodiment, group programming is performed to program several transistors at the same time, instead of one transistor at a time. For example, two configurations (e.g., two sets of VD vias) are pre-developed and stored, e.g., in a library, for data “0000”. One of the pre-developed configurations corresponds to the programmed configurations of the transistors T1, T5, T9, T13 (e.g., the set of VD vias 550-554) in FIG. 5A, and the other of the pre-developed configurations corresponds to the programmed configurations of the transistors T2, T6, T10, T14 (e.g., the corresponding set of VD vias) in FIG. 5A. When data “0000” are to be programed into a set or string of four transistors, one of the pre-developed configurations is selected and used for programming the string of four transistors at the same time. The selection of one of the pre-developed configurations to be used is made based on a previously programed, directly adjacent transistor, in a manner similar to that described with respect to the programming of the transistor T13.

Similarly, the programed configurations of the transistors T3, T7, T11, T15 include an example of programming data “0010”, whereas the programed configurations of the transistors T4, T8, T12, T16 include another example of programming the same data “0010”. In at least one embodiment, for group programming, two configurations (e.g., two sets of VD vias) are pre-developed and stored, e.g., in a library, for data “0010”. One of the pre-developed configurations corresponds to the programmed configurations of the transistors T3, T7, T11, T15 in FIG. 5A, and the other of the pre-developed configurations corresponds to the programmed configurations of the transistors T4, T8, T12, T16 in FIG. 5A. When data “0010” are to be programed into a set or string of four transistors, one of the pre-developed configurations is selected and used for programming the string of four transistors at the same time. The selection of one of the pre-developed configurations to be used is made based on a previously programed, directly adjacent transistor, in a manner similar to that described with respect to the programming of the transistor T13. The described examples of group programming for four transistors are examples. Any other numbers of transistors are usable for group programming in accordance with some embodiments.

FIG. 5B includes a schematic circuit diagram of a circuit region 500B, and a schematic view of a layout corresponding to the circuit region 500B. The layout includes the ROM cell 505A and a portion of a ROM cell 505B. Like the ROM cell 505A, the ROM cell 505B is a programmed instance of the unprogrammed ROM cell 405.

The ROM cell 505B has a boundary 510 corresponding to the boundary 410. The ROM cell 505B is placed in abutment with the ROM cell 505A along a common edge of the boundary 510 and the boundary 410. The common edge is the edge 413 of the boundary 410. The ROM cell 505A and the ROM cell 505B share a set of common MD contact structures including the MD contact structure MD0 and arranged on the edge 413. In other words, the ROM cell 505A and the ROM cell 505B share a set of common source/drains underlying the set of common MD contact structures.

The ROM cell 505B includes 16 transistors in a 4×4 arrangement. Transistors T17-T20 of the ROM cell 505B are illustrated in FIG. 5B, whereas the other transistors are omitted for simplicity. The transistors T17-T20 of the ROM cell 505B correspond to the transistors T13-T16 of the ROM cell 505A. The transistors T17-T20 of the ROM cell 505B and the transistors T1-T4 of the ROM cell 505A are directly adjacent to each other, and share the set of common source/drains arranged on the edge 413. The transistors T17-T20 are configured correspondingly by the active regions OD0-OD3 with a gate GK. In some embodiments, the gate GK in FIG. 5B corresponds to the gate GK described with respect to FIG. 3B. In an example embodiment, the ROM cell 505A corresponds to Cell_0 and the ROM cell 505B corresponds to Cell_1 in FIG. 4. The active regions OD0-OD3, bit lines BL0-BL3 and the VSS power rails 443, 446, 450, 453 extend continuously along the X axis through the ROM cell 505A and the ROM cell 505B.

The ROM cell 505B is programmed to store codes 506-509. For simplicity, data to be stored by the transistors T17-T20 are shown in the codes 506-509 in FIG. 5B, whereas data to be stored by the other transistors of the ROM cell 505B are omitted. Logic “0” in the code 506 is programed into the transistor T17 based on the programed configuration of the transistor T1, or based on the electrical connection of the common source/drain of the transistor T1 and the transistor T17 directly adjacent thereto. Because the common source/drain of the transistor T1 and the transistor T17 is coupled to the VSS power rail 443 by the VD via 550 when the transistor T1 is programed, the other source/drain of the transistor T17 is also coupled to the VSS power rail 443 so as to program logic “0” into the transistor T17 in accordance with the OFF configuration 0f. For this purpose, the APR tool is configured to generate a VD via 55K electrically coupling an MD contact structure MDK over the other source/drain of the transistor T17 to the VSS power rail 443.

Similarly, the transistor T18 is programmed to have the OFF configuration 0i based on the programed configuration of the transistor T2, and the transistor T19 is programmed to have the OFF configuration 0f based on the programed configuration of the transistor T3. The APR tool is configured to generate corresponding VD vias corresponding to the programed configurations of the transistors T18, T19, as illustrated in the ROM cell 505B.

Logic “1” in the code 509 is programed into the transistor T20 based on the programed configuration of the transistor T4. Because the common source/drain of the transistor T4 and the transistor T20 is coupled to the bit line BL3 when the transistor T4 is programed, the other source/drain of the transistor T20 is coupled to the VSS power rail 453 so as to program logic “1” into the transistor T20 in accordance with the ON configuration 1g. For this purpose, the APR tool is configured to generate a VD via 559 electrically coupling an MD contact structure 558 over the other source/drain of the transistor T20 to the VSS power rail 453. In some embodiments, group programming described with respect to FIG. 5A is performed for the ROM cell 505B and/or other ROM cells in a ROM array.

FIG. 5C includes a schematic circuit diagram of a circuit region 500C, and a schematic view of a layout of a ROM cell 505C corresponding to the circuit region 500C. The ROM cell 505C is a programmed instance of the unprogrammed ROM cell 405.

Codes 581-584 are programed into the transistors T1-T16 of the ROM cell 505C in manners similar to those described with respect to FIGS. 5A-5B. For example, to store the code 581, the transistors T13, T9, T5, T1 are sequentially programed from right to left to correspondingly have the OFF configuration 0i, the OFF configuration 0i, the ON configuration Ig, the OFF configuration 0f. The APR tool is configured to generate a set of VD vias 564, 563, 562, 551, 550 corresponding to the programed configurations of the transistors T13, T9, T5, T1, as illustrated in the ROM cell 505C.

In FIG. 5C, the programed configurations of the transistors T1, T5, T9, T13 include an example of programming data “0100”, whereas the programed configurations of the transistors T2, T6, T10, T14 include another example of programming the same data “0100”. In at least one embodiment, the programed configurations of the transistors T1, T5, T9, T13 (or the set of VD vias 550, 551, 562, 563, 564) and the programed configurations of the transistors T2, T6, T10, T14 (or the corresponding set of VD vias) are pre-developed and stored, e.g., in a library, for group programming of data “0100”, as described herein.

Similarly, the programed configurations of the transistors T3, T7, T11, T15 include an example of programming data “0110”, whereas the programed configurations of the transistors T4, T8, T12, T16 include another example of programming the same data “0110”. In at least one embodiment, the programed configurations of the transistors T3, T7, T11, T15 (or the corresponding set of VD vias) and the programed configurations of the transistors T4, T8, T12, T16 (or the corresponding set of VD vias) are pre-developed and stored, e.g., in a library, for group programming of data “0110”, as described herein.

FIG. 5D includes a schematic circuit diagram of a circuit region 500D, and a schematic view of a layout of a ROM cell 505D corresponding to the circuit region 500D. The ROM cell 505D is a programmed instance of the unprogrammed ROM cell 405.

Codes 586-589 are programed into the transistors T1-T16 of the ROM cell 505D in manners similar to those described with respect to FIGS. 5A-5B. For example, to store the code 586, the transistors T13, T9, T5, T1 are sequentially programed from right to left to correspondingly have the OFF configuration 0i, the OFF configuration 0i, the OFF configuration 0i, the ON configuration 1g. The APR tool is configured to generate a set of VD vias 564, 563, 562, 571, 550 corresponding to the programed configurations of the transistors T13, T9, T5, T1, as illustrated in the ROM cell 505D.

In FIG. 5D, the programed configurations of the transistors T1, T5, T9, T13 include an example of programming data “1000”, whereas the programed configurations of the transistors T2, T6, T10, T14 include another example of programming the same data “1000”. In at least one embodiment, the programed configurations of the transistors T1, T5, T9, T13 (or the set of VD vias 550, 571, 562, 563, 564) and the programed configurations of the transistors T2, T6, T10, T14 (or the corresponding set of VD vias) are pre-developed and stored, e.g., in a library, for group programming of data “1000”, as described herein.

Similarly, the programed configurations of the transistors T3, T7, T11, T15 include an example of programming data “1010”, whereas the programed configurations of the transistors T4, T8, T12, T16 include another example of programming the same data “1010”. In at least one embodiment, the programed configurations of the transistors T3, T7, T11, T15 (or the corresponding set of VD vias) and the programed configurations of the transistors T4, T8, T12, T16 (or the corresponding set of VD vias) are pre-developed and stored, e.g., in a library, for group programming of data “1010”, as described herein.

FIG. 5E includes a schematic circuit diagram of a circuit region 500E, and a schematic view of a layout of a ROM cell 505E corresponding to the circuit region 500E. The ROM cell 505E is a programmed instance of the unprogrammed ROM cell 405.

Codes 591-594 are programed into the transistors T1-T16 of the ROM cell 505E in manners similar to those described with respect to FIGS. 5A-5B. For example, to store the code 591, the transistors T13, T9, T5, T1 are sequentially programed from right to left to correspondingly have the OFF configuration 0f, the OFF configuration 0f, the ON configuration 1h, the ON configuration 1g. The APR tool is configured to generate a set of VD vias 554, 553, 552, 571, 550 corresponding to the programed configurations of the transistors T13, T9, T5, T1, as illustrated in the ROM cell 505E.

In FIG. 5E, the programed configurations of the transistors T1, T5, T9, T13 include an example of programming data “1100”, whereas the programed configurations of the transistors T2, T6, T10, T14 include another example of programming the same data “1100”. In at least one embodiment, the programed configurations of the transistors T1, T5, T9, T13 (or the set of VD vias 550, 571, 552, 553, 554) and the programed configurations of the transistors T2, T6, T10, T14 (or the corresponding set of VD vias) are pre-developed and stored, e.g., in a library, for group programming of data “1100”, as described herein.

Similarly, the programed configurations of the transistors T3, T7, T11, T15 include an example of programming data “1110”, whereas the programed configurations of the transistors T4, T8, T12, T16 include another example of programming the same data “1110”. In at least one embodiment, the programed configurations of the transistors T3, T7, T11, T15 (or the corresponding set of VD vias) and the programed configurations of the transistors T4, T8, T12, T16 (or the corresponding set of VD vias) are pre-developed and stored, e.g., in a library, for group programming of data “1110”, as described herein.

FIGS. 6A-6F each include a schematic circuit diagram and a schematic view of a layout of a circuit region of a memory device, in accordance with some embodiments. FIGS. 6A-6F show non-limiting examples of ROM programming using the Code Pattern 2, i.e., using the configurations described with respect to FIGS. 2A-2G. For simplicity, corresponding components in FIGS. 1, 2A-2G, 3A-3C, 4, 5A-5E, 6A-6F are designated by the same reference numerals.

FIG. 6A includes a schematic circuit diagram of a circuit region 600A, and a schematic view of a layout of a ROM cell 605A corresponding to the circuit region 600A. The ROM cell 605A is a programmed instance of the unprogrammed ROM cell 405.

Codes 601-604 are programed into the transistors T1-T16 of the ROM cell 605A in manners similar to those described with respect to FIGS. 5A-5B. For example, to store the code 601, the transistors T13, T9, T5, T1 are sequentially programed from right to left to all have the OFF configuration Ga in FIG. 2E. Because all source/drains of the transistors T1, T5, T9, T13 are electrically floating, the APR tool is configured to generate a set of five “nil” VD vias, i.e., no VD vias, for the five corresponding MD contact structures MD0-MD4, in accordance with the programed configurations of the transistors T1, T5, T9, T13, as illustrated in the ROM cell 605A.

To store the code 602, the transistors T14, T10, T6, T2 are sequentially programed from right to left to correspondingly have the OFF configuration Ga in FIG. 2E, the OFF configuration Ga in FIG. 2E, the OFF configuration Ga in FIG. 2G, the OFF configuration 0i. The APR tool is configured to generate a set of VD vias which include VD vias 606, 607 and three “nil” VD vias, i.e., no VD vias, for the three corresponding MD contact structures, in accordance with the programed configurations of the transistors T2, T6, T10, T14, as illustrated in the ROM cell 605A.

To store the code 603, the transistors T15, T11, T7, T3 are sequentially programed from right to left to correspondingly have the OFF configuration Ga in FIG. 2E, the OFF configuration Ga in FIG. 2E, the OFF configuration Oa in FIG. 2F, the OFF configuration 0f. The APR tool is configured to generate a set of VD vias which include VD vias 608, 609 and three “nil” VD vias, i.e., no VD vias, for the three corresponding MD contact structures, in accordance with the programed configurations of the transistors T3, T7, T11, T15, as illustrated in the ROM cell 605A.

The code 604 is programed into the transistors T4, T8, T12, T16 in the same manner as the transistors T1, T5, T9, T13.

In FIG. 6A, the programed configurations of the transistors T1, T5, T9, T13 include a first example of programming data “0000”, the programed configurations of the transistors T2, T6, T10, T14 include a second example of programming the same data “0000”, the programed configurations of the transistors T3, T7, T11, T15 include a third example of programming the same data “0000”. Other examples of programming the same data “0000” are within the scopes of various embodiments, given the various OFF configurations described with respect to FIGS. 2C-2G and usable in accordance with the Code Pattern 2. In at least one embodiment, the programed configurations of the transistors T1, T5, T9, T13, the programed configurations of the transistors T2, T6, T10, T14, the programed configurations of the transistors T3, T7, T11, T15, and/or one or more further examples of programming the data “0000” are pre-developed and stored, e.g., in a library, for group programming of data “0000”, as described herein.

In some embodiments, compared to the Code Pattern 1, the Code Pattern 2 provides a greater number of options for programming the same data or code, which advantageously increases flexibility of circuit designs. In at least one embodiment, to program the same data or code, the Code Pattern 2 sometimes requires fewer VD vias than the Code Pattern 1, which advantageously reduces requirements for routing resources, and/or reduces parasitic capacitance which in turn improves performance.

FIG. 6B includes a schematic circuit diagram of a circuit region 600B, and a schematic view of a layout of a ROM cell 605B corresponding to the circuit region 600B. The ROM cell 605B is a programmed instance of the unprogrammed ROM cell 405.

Codes 611-614 are programed into the transistors T1-T16 of the ROM cell 605B in manners similar to those described with respect to FIGS. 5A-5B. For example, the code 611 is programed into the transistors T1, T5, T9, T13 in the same manner as the code 601 described with respect to FIG. 6A.

To store the code 612, the transistors T14, T10, T6, T2 are sequentially programed from right to left to correspondingly have the OFF configuration Oa in FIG. 2F, the ON configuration 1h, the OFF configuration 0i, the OFF configuration 0i. The APR tool is configured to generate a set of VD vias which include four VD vias and a “nil” VD via, in accordance with the programed configurations of the transistors T2, T6, T10, T14, as illustrated in the ROM cell 605B.

To store the code 613, the transistors T15, T11, T7, T3 are sequentially programed from right to left to correspondingly have the OFF configuration Oa in FIG. 2G, the ON configuration 1g, the OFF configuration 0f, the OFF configuration 0f. The APR tool is configured to generate a set of VD vias which include four VD vias and a “nil” VD via, in accordance with the programed configurations of the transistors T3, T7, T11, T15, as illustrated in the ROM cell 605B.

To store the code 614, the transistors T16, T12, T8, T4 are sequentially programed from right to left to correspondingly have the OFF configuration Oa in FIG. 2G, the ON configuration 1g, the OFF configuration Oa in FIG. 2F, the OFF configuration Oa in FIG. 2E. The APR tool is configured to generate a set of VD vias which include two “nil” VD vias, two VD vias, and another “nil” VD via, in accordance with the programed configurations of the transistors T4, T8, T12, T16, as illustrated in the ROM cell 605B.

In FIG. 6B, the programed configurations of the transistors T2, T6, T10, T14 include a first example of programming data “0010”, the programed configurations of the transistors T3, T7, T11, T15 include a second example of programming the same data “0010”, the programed configurations of the transistors T4, T8, T12, T16 include a third example of programming the same data “0010”. Other examples of programming the same data “0010” are within the scopes of various embodiments. In at least one embodiment, the programed configurations of the transistors T2, T6, T10, T14, the programed configurations of the transistors T3, T7, T11, T15, the programed configurations of the transistors T4, T8, T12, T16 and/or one or more further examples of programming the data “0010” are pre-developed and stored, e.g., in a library, for group programming of data “0010”, as described herein.

FIG. 6C includes a schematic circuit diagram of a circuit region 600C, and a schematic view of a layout of a ROM cell 605C corresponding to the circuit region 600C. The ROM cell 605C is a programmed instance of the unprogrammed ROM cell 405.

Codes 621-624 are programed into the transistors T1-T16 of the ROM cell 605C in manners similar to those described with respect to FIGS. 5A-5B. For example, the code 621 is programed into the transistors T1, T5, T9, T13 in the same manner as the code 601 described with respect to FIG. 6A.

To store the code 622, the transistors T14, T10, T6, T2 are sequentially programed from right to left to correspondingly have the OFF configuration Ga in FIG. 2E, the OFF configuration Ga in FIG. 2F, the ON configuration 1h, the OFF configuration 0i. The APR tool is configured to generate a set of VD vias which include three VD vias and two “nil” VD vias, in accordance with the programed configurations of the transistors T2, T6, T10, T14, as illustrated in the ROM cell 605C.

To store the code 623, the transistors T15, T11, T7, T3 are sequentially programed from right to left to correspondingly have the OFF configuration Ga in FIG. 2E, the OFF configuration Ga in FIG. 2G, the ON configuration 1g, the OFF configuration 0f. The APR tool is configured to generate a set of VD vias which include three VD vias and two “nil” VD vias, in accordance with the programed configurations of the transistors T3, T7, T11, T15, as illustrated in the ROM cell 605C.

To store the code 624, the transistors T16, T12, T8, T4 are sequentially programed from right to left to correspondingly have the OFF configuration Oa in FIG. 2E, the OFF configuration Ga in FIG. 2G, the ON configuration 1g, the OFF configuration Ga in FIG. 2F. The APR tool is configured to generate a set of VD vias which include a “nil” VD via, two VD vias, and two further “nil” VD vias, in accordance with the programed configurations of the transistors T4, T8, T12, T16, as illustrated in the ROM cell 605C.

In FIG. 6C, the programed configurations of the transistors T2, T6, T10, T14 include a first example of programming data “0100”, the programed configurations of the transistors T3, T7, T11, T15 include a second example of programming the same data “0100”, the programed configurations of the transistors T4, T8, T12, T16 include a third example of programming the same data “0100”. Other examples of programming the same data “0100” are within the scopes of various embodiments. In at least one embodiment, the programed configurations of the transistors T2, T6, T10, T14, the programed configurations of the transistors T3, T7, T11, T15, the programed configurations of the transistors T4, T8, T12, T16 and/or one or more further examples of programming the data “0100” are pre-developed and stored, e.g., in a library, for group programming of data “0100”, as described herein.

FIG. 6D includes a schematic circuit diagram of a circuit region 600D, and a schematic view of a layout of a ROM cell 605D corresponding to the circuit region 600D. The ROM cell 605D is a programmed instance of the unprogrammed ROM cell 405.

Codes 631-634 are programed into the transistors T1-T16 of the ROM cell 605D in manners similar to those described with respect to FIGS. 5A-5B. For example, the code 631 is programed into the transistors T1, T5, T9, T13 in the same manner as the code 601 described with respect to FIG. 6A.

To store the code 632, the transistors T14, T10, T6, T2 are sequentially programed from right to left to correspondingly have the OFF configuration Ga in FIG. 2G, the ON configuration 1g, the ON configuration 1h, the OFF configuration 0i. The APR tool is configured to generate a set of VD vias which include four VD vias and a “nil” VD via, in accordance with the programed configurations of the transistors T2, T6, T10, T14, as illustrated in the ROM cell 605D.

To store the code 633, the transistors T15, T11, T7, T3 are sequentially programed from right to left to correspondingly have the OFF configuration Ga in FIG. 2F, the ON configuration 1h, the ON configuration 1g, the OFF configuration 0f. The APR tool is configured to generate a set of VD vias which include four VD vias and a “nil” VD via, in accordance with the programed configurations of the transistors T3, T7, T11, T15, as illustrated in the ROM cell 605D.

To store the code 634, the transistors T16, T12, T8, T4 are sequentially programed from right to left to correspondingly have the OFF configuration Oa in FIG. 2F, the ON configuration 1h, the ON configuration 1g, the OFF configuration Oa in FIG. 2F. The APR tool is configured to generate a set of VD vias which include a “nil” VD via, three VD vias, and a further “nil” VD via, in accordance with the programed configurations of the transistors T4, T8, T12, T16, as illustrated in the ROM cell 605D.

In FIG. 6D, the programed configurations of the transistors T2, T6, T10, T14 include a first example of programming data “0110”, the programed configurations of the transistors T3, T7, T11, T15 include a second example of programming the same data “0110”, the programed configurations of the transistors T4, T8, T12, T16 include a third example of programming the same data “0110”. Other examples of programming the same data “0110” are within the scopes of various embodiments. In at least one embodiment, the programed configurations of the transistors T2, T6, T10, T14, the programed configurations of the transistors T3, T7, T11, T15, the programed configurations of the transistors T4, T8, T12, T16 and/or one or more further examples of programming the data “0110” are pre-developed and stored, e.g., in a library, for group programming of data “0110”, as described herein.

FIG. 6E includes a schematic circuit diagram of a circuit region 600E, and a schematic view of a layout of a ROM cell 605E corresponding to the circuit region 600E. The ROM cell 605E is a programmed instance of the unprogrammed ROM cell 405.

Codes 641-644 are programed into the transistors T1-T16 of the ROM cell 605E in manners similar to those described with respect to FIGS. 5A-5B. For example, to store the code 641, the transistors T13, T9, T5, T1 are sequentially programed from right to left to correspondingly have the OFF configuration Oa in FIG. 2E, the OFF configuration Oa in FIG. 2E, the OFF configuration Oa in FIG. 2G, the ON configuration 1g. The APR tool is configured to generate a set of VD vias which include two VD vias and three “nil” VD vias, in accordance with the programed configurations of the transistors T1, T5, T9, T13, as illustrated in the ROM cell 605E.

To store the code 642, the transistors T14, T10, T6, T2 are sequentially programed from right to left to correspondingly have the OFF configuration Oa in FIG. 2E, the OFF configuration Oa in FIG. 2E, the OFF configuration Oa in FIG. 2F, the ON configuration 1h. The APR tool is configured to generate a set of VD vias which include two VD vias and three “nil” VD vias, in accordance with the programed configurations of the transistors T2, T6, T10, T14, as illustrated in the ROM cell 605E.

The programed configurations of the transistors T1, T5, T9, T13 include a first example of programming data “1000”, and the programed configurations of the transistors T2, T6, T10, T14 include a second example of programming the same data “1000”. Other examples of programming the same data “1000” are within the scopes of various embodiments. In at least one embodiment, the programed configurations of the transistors T1, T5, T9, T13, the programed configurations of the transistors T2, T6, T10, T14, and/or one or more further examples of programming the data “1000” are pre-developed and stored, e.g., in a library, for group programming of data “1000”, as described herein.

To store the code 643, the transistors T15, T11, T7, T3 are sequentially programed from right to left to correspondingly have the OFF configuration Oa in FIG. 2F, the ON configuration 1h, the OFF configuration 0i, the ON configuration 1g. The APR tool is configured to generate a set of VD vias which include four VD vias and a “nil” VD via, in accordance with the programed configurations of the transistors T3, T7, T11, T15, as illustrated in the ROM cell 605E.

To store the code 644, the transistors T16, T12, T8, T4 are sequentially programed from right to left to correspondingly have the OFF configuration Oa in FIG. 2F, the ON configuration 1g, the OFF configuration 0f, the ON configuration 1h. The APR tool is configured to generate a set of VD vias which include four VD vias and a “nil” VD via, in accordance with the programed configurations of the transistors T4, T8, T12, T16, as illustrated in the ROM cell 605E.

The programed configurations of the transistors T3, T7, T11, T15 include a first example of programming data “1010”, and the programed configurations of the transistors T4, T8, T12, T16 include a second example of programming the same data “1010”. Other examples of programming the same data “1010” are within the scopes of various embodiments. In at least one embodiment, the programed configurations of the transistors T3, T7, T11, T15, the programed configurations of the transistors T4, T8, T12, T16 and/or one or more further examples of programming the data “1010” are pre-developed and stored, e.g., in a library, for group programming of data “1010”, as described herein.

FIG. 6F includes a schematic circuit diagram of a circuit region 600F, and a schematic view of a layout of a ROM cell 605F corresponding to the circuit region 600F. The ROM cell 605F is a programmed instance of the unprogrammed ROM cell 405.

Codes 651-654 are programed into the transistors T1-T16 of the ROM cell 605F in manners similar to those described with respect to FIGS. 5A-5B. For example, to store the code 651, the transistors T13, T9, T5, T1 are sequentially programed from right to left to correspondingly have the OFF configuration Ga in FIG. 2E, the OFF configuration Ga in FIG. 2F, the ON configuration 1h, the ON configuration 1g. The APR tool is configured to generate a set of VD vias which include three VD vias and two “nil” VD vias, in accordance with the programed configurations of the transistors T1, T5, T9, T13, as illustrated in the ROM cell 605F.

To store the code 652, the transistors T14, T10, T6, T2 are sequentially programed from right to left to correspondingly have the OFF configuration Ga in FIG. 2E, the OFF configuration Ga in FIG. 2G, the ON configuration 1g, the ON configuration 1h. The APR tool is configured to generate a set of VD vias which include three VD vias and two “nil” VD vias, in accordance with the programed configurations of the transistors T2, T6, T10, T14, as illustrated in the ROM cell 605F.

The programed configurations of the transistors T1, T5, T9, T13 include a first example of programming data “1100”, and the programed configurations of the transistors T2, T6, T10, T14 include a second example of programming the same data “1100”. Other examples of programming the same data “1100” are within the scopes of various embodiments. In at least one embodiment, the programed configurations of the transistors T1, T5, T9, T13, the programed configurations of the transistors T2, T6, T10, T14, and/or one or more further examples of programming the data “1100” are pre-developed and stored, e.g., in a library, for group programming of data “1100”, as described herein.

To store the code 653, the transistors T15, T11, T7, T3 are sequentially programed from right to left to correspondingly have the OFF configuration Ga in FIG. 2G, the ON configuration 1g, the ON configuration 1h, the ON configuration 1g. The APR tool is configured to generate a set of VD vias which include four VD vias and a “nil” VD via, in accordance with the programed configurations of the transistors T3, T7, T11, T15, as illustrated in the ROM cell 605F.

To store the code 654, the transistors T16, T12, T8, T4 are sequentially programed from right to left to correspondingly have the OFF configuration Ga in FIG. 2F, the ON configuration 1h, the ON configuration 1g, the ON configuration 1h. The APR tool is configured to generate a set of VD vias which include four VD vias and a “nil” VD via, in accordance with the programed configurations of the transistors T4, T8, T12, T16, as illustrated in the ROM cell 605F.

The programed configurations of the transistors T3, T7, T11, T15 include a first example of programming data “1110”, and the programed configurations of the transistors T4, T8, T12, T16 include a second example of programming the same data “1110”. Other examples of programming the same data “1110” are within the scopes of various embodiments. In at least one embodiment, the programed configurations of the transistors T3, T7, T11, T15, the programed configurations of the transistors T4, T8, T12, T16 and/or one or more further examples of programming the data “1110” are pre-developed and stored, e.g., in a library, for group programming of data “1110”, as described herein.

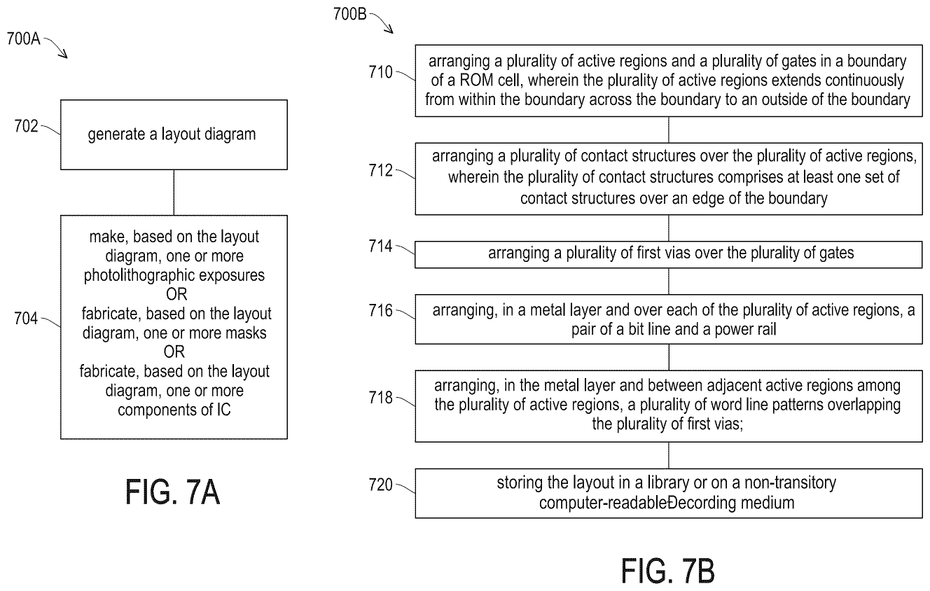

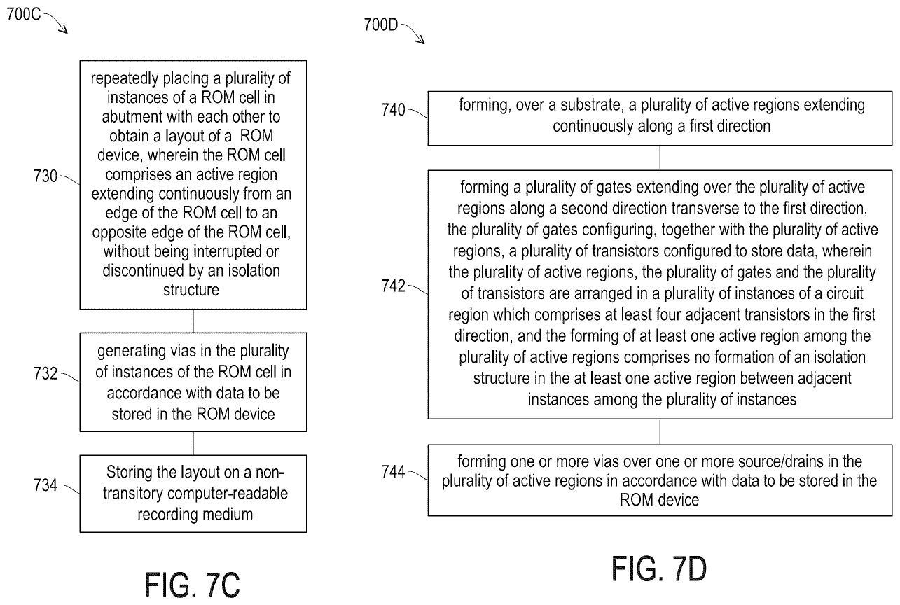

FIG. 7A is a flowchart of a method 700A of generating a layout and using the layout to manufacture an IC device, in accordance with some embodiments. Method 700A is implementable, for example, using an EDA system and/or an integrated circuit (IC) manufacturing system as described herein, in accordance with some embodiments. Regarding method 700A, examples of the layout include the layouts disclosed herein, or the like. Examples of an IC device to be manufactured according to method 700A include one or more of the memory devices, such as ROM devices, disclosed herein. Method 700A comprises operations 702, 704.

At operation 702, a layout is generated which, among other things, includes at least one ROM cell with at least one active region extending continuously through the ROM cell, as described herein. Examples of operation 702 are described with respect to FIGS. 7B-7C.

At operation 704, based on the layout, at least one of (A) one or more photolithographic exposures are made or (B) one or more semiconductor masks are fabricated or (C) one or more components in a layer of an IC device are fabricated. Examples of operation 704 are described with respect to FIG. 7D.

FIG. 7B is a flowchart of a method 700B of generating a layout for a read-only memory (ROM) cell. The method 700B is performed at least partially by a processor. In some embodiments, the method 700B is performed to generate a ROM cell corresponding to the ROM cell 405. The method 700B comprises operations 710, 712, 714, 716, 718, 720.

At operation 710, a plurality of active regions and a plurality of gates are arranged in a boundary of a ROM cell, wherein the plurality of active regions extends continuously from within the boundary across the boundary to an outside of the boundary. For example, as described with respect to FIG. 4, a plurality of active regions OD0-OD3 and a plurality of gates G0-G3 are arranged in a boundary 410 of a ROM cell 405. The active regions OD0-OD3 extend continuously from within the boundary 410, across the boundary 410, to an outside of the boundary 410.

At operation 712, a plurality of contact structures is arranged over the plurality of active regions, wherein the plurality of contact structures comprises at least one set of contact structures over an edge of the boundary. For example, as described with respect to FIG. 4, a plurality of MD contact structures is arranged over the active regions OD0-OD3. The plurality of MD contact structures comprises at least one set of MD contact structures over an edge, e.g., the edge 413 or the edge 414, of the boundary 410.

At operation 714, a plurality of first vias is arranged over the plurality of gates. For example, as described with respect to FIG. 4, a plurality of VG vias VG0-VG3 is arranged correspondingly over the plurality of gates G0-G3.

At operation 716, a pair of a bit line and a power rail is arranged in a metal layer and over each of the plurality of active regions. For example, as described with respect to FIG. 4, in an M0 layer, a pair of a bit line BL0 and a VSS power rail 443 is arranged over the active region OD0, a pair of a bit line BL1 and a VSS power rail 446 is arranged over the active region OD1, or the like.

At operation 718, a plurality of word line patterns overlapping the plurality of first vias is arranged in the metal layer and between adjacent active regions among the plurality of active regions. For example, as described with respect to FIG. 4, in the M0 layer, word line patterns 444, 445 are arranged between adjacent active regions OD0, OD1 to correspondingly overlap the VG vias VG3, VG1, and word line patterns 451, 452 are arranged between adjacent active regions OD2, OD3 to correspondingly overlap the VG vias VG2, VG0.

At operation 720, the obtained layout of the ROM cell is stored in a library or on a non-transitory computer-readable recording medium, e.g., for later retrieval and use for generating a layout of a ROM array, as described with respect to FIG. 7C. In some embodiments, the stored ROM cell 405 is free of VD vias which will be added later in a ROM programming operation, as described herein. One or more advantages described herein are achievable by a ROM cell generated by the method 700B, in accordance with some embodiments.

FIG. 7C is a flowchart of a method 700C of generating a layout for a read-only memory (ROM) device. The method 700C is performed at least partially by a processor. In some embodiments, the method 700C is performed to generate a layout for a ROM device corresponding to one or more of the memory devices and/or ROM devices described herein. The method 700C comprises operations 730, 732, 734.

At operation 730, a plurality of instances of a ROM cell is repeatedly placed in abutment with each other to obtain a layout of the ROM device. The ROM cell comprises an active region extending continuously from an edge of the ROM cell to an opposite edge of the ROM cell, without being interrupted or discontinued by an isolation structure. For example, as described with respect to FIG. 4, a plurality of instances, e.g., Cell_0 to Cell_3, of a ROM cell 405 is repeatedly placed in abutment with each other to obtain a layout of a memory device 400. The ROM cell 405 comprises an active region (e.g., any of active regions OD0-OD3) that extends continuously from an edge 413 of the ROM cell 405 to an opposite edge 414 of the ROM cell 405, without being interrupted or discontinued by an isolation structure.

At operation 732, vias are generated in the plurality of instances of the ROM cell in accordance with data to be stored in the ROM device. For example, as described with respect to one or more of FIGS. 5A-5E, 6A-6F, VD vias are added to various bitcells in the instances of the ROM cell 405, in accordance with data to be stored. To program a bitcell to store logic “1”, two VD vias are added to couple one source/drain of a transistor in the bitcell to a bit line BL and to couple the other source/drain of the transistor to a VSS power rail, as described with respect to FIGS. 2A, 2B. To program a bitcell to store logic “0”, two VD vias are added to couple both source/drains of a transistor in the bitcell to a bit line BL, or to couple both source/drains of the transistor to a VSS power rail, as described with respect to FIGS. 2C, 2D. Alternatively, to program a bitcell to store logic “0”, no VD vias are added as described with respect to FIG. 2E, or only one VD via is added to couple one source/drain of a transistor in the bitcell to a bit line BL or to a VSS power rail as described with respect to FIGS. 2F, 2G. In some embodiments, bitcells are sequentially programed one by one along a bit line, or group programming is performed to program multiple bitcells at the same time.

At operation 734, the obtained layout of the programmed ROM device is stored on a non-transitory computer-readable recording medium, e.g., for later retrieval and use in manufacturing ROM devices, as described with respect to FIG. 7D. One or more advantages described herein are achievable by a layout of the ROM device generated by the method 700C, in accordance with some embodiments.

FIG. 7D is a flowchart of a method 700D of manufacturing a ROM device, in accordance with some embodiments. In some embodiments, the method 700D is performed to manufacture a ROM device corresponding to one or more of the memory devices and/or ROM devices described herein. The method 700D comprises operations 740, 742, 744.

At operation 740, a plurality of active regions extending continuously along a first direction is formed over a substrate. For example, as described with respect to FIG. 3C, an example active region corresponding to source/drains 322, 323 and a channel therebetween is formed along the X axis over a substrate 320. In some embodiments, the active region includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material. In some embodiments, an active region comprises a nano-sheet structure, e.g., a continuous volume of one or more layers of one or more semiconductor materials. In various embodiments, individual nano-sheet layers include a single monolayer or multiple monolayers of a given semiconductor material.

At operation 742, a plurality of gates is formed along a second direction transverse to the first direction to extend over the plurality of active regions. The plurality of gates configures, together with the plurality of active regions, a plurality of transistors configured to store data. For example, as described with respect to FIG. 3C, an example gate 325 is formed along the Y axis to extend over the active region to configure therewith a transistor 321. In some embodiments, a gate is a part of a gate structure and includes one or more conductive materials, e.g., polysilicon, copper (Cu), aluminum (Al), tungsten (W), cobalt (Co), ruthenium (Ru), or one or more other metals or other suitable materials. The gate structure further comprises a gate dielectric layer including one or more insulating materials, e.g., silicon dioxide, silicon nitride (Si₃N₄), and/or one or more other suitable material such as a low-k material having a k value less than 3.8, or a high-k material having a k value greater than 3.8, such as aluminum oxide (Al₂O₃), hafnium oxide (HfO₂), tantalum pentoxide (Ta₂O₅), or titanium oxide (TiO₂).

The plurality of active regions, the plurality of gates and the plurality of transistors are arranged in a plurality of instances of a circuit region which comprises at least four adjacent transistors in the first direction. For example, as described with respect to FIG. 4, various active regions, gates and transistors are arranged in a plurality of instances Cell_0 to Cell_3 of a circuit region, e.g., a ROM cell 405. The ROM cell 405 comprises four transistors (e.g., transistors T1, T5, T9, T13 described with respect to FIG. 5A) adjacent each other along the X axis.

The forming of at least one active region among the plurality of active regions comprises no formation of an isolation structure in the at least one active region between adjacent instances among the plurality of instances. For example, as described with respect to FIG. 5B, no isolation structure is formed in any of the active regions OD0-OD3 between adjacent instances 505A, 505B of the ROM cell 405.

At operation 744, one or more vias are formed over one or more source/drains in the plurality of active regions in accordance with data to be stored in the ROM device. For example, as described with respect to FIG. 3C, one or more of VD vias 328, 329 are formed to couple corresponding source/drains 322, 323 to a bit line BL or a VSS power rail, e.g., in the M0 layer. Various examples of VD vias formed in accordance with the data to be stored are described with respect to FIGS. 5A-5E, 6A-6F. As a result, the ROM device is programed. In at least one embodiment, one or more advantages described herein are achievable by a ROM device manufactured in accordance with the method 700D.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

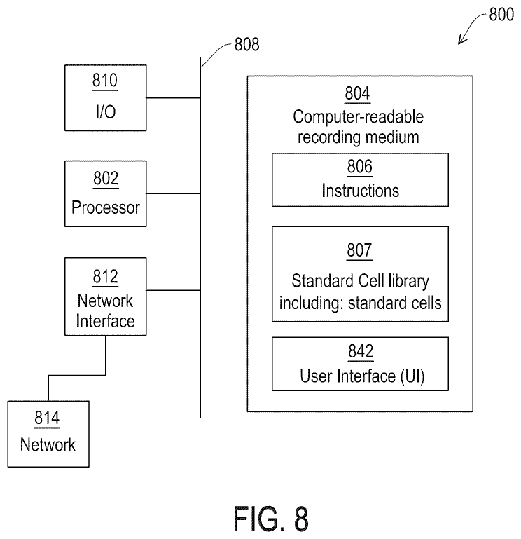

FIG. 8 is a block diagram of an electronic design automation (EDA) system 800 in accordance with some embodiments.

In some embodiments, EDA system 800 includes an APR system. Methods described herein of designing layouts represent wire routing arrangements, in accordance with one or more embodiments, are implementable, for example, using EDA system 800, in accordance with some embodiments.

In some embodiments, EDA system 800 is a general purpose computing device including a hardware processor 802 and a non-transitory, computer-readable recording medium 804. Recording medium 804, amongst other things, is encoded with, i.e., stores, computer program code 806, i.e., a set of executable instructions. Execution of instructions 806 by hardware processor 802 represents (at least in part) an EDA tool which implements a portion or all of the methods described herein in accordance with one or more embodiments (hereinafter, the noted processes and/or methods).

Processor 802 is electrically coupled to computer-readable recording medium 804 via a bus 808. Processor 802 is also electrically coupled to an I/O interface 810 by bus 808. A network interface 812 is also electrically connected to processor 802 via bus 808. Network interface 812 is connected to a network 814, so that processor 802 and computer-readable recording medium 804 are capable of connecting to external elements via network 814. Processor 802 is configured to execute computer program code 806 encoded in computer-readable recording medium 804 in order to cause system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable recording medium 804 is an electronic, magnetic, optical, electromagnetic, infrared, and/or a semiconductor system (or apparatus or device). For example, computer-readable recording medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 804 includes a compact disk-read only memory (CD-ROM), a compact disk-read/write (CD-R/W), and/or a digital video disc (DVD).

In one or more embodiments, recording medium 804 stores computer program code 806 configured to cause system 800 (where such execution represents (at least in part) the EDA tool) to be usable for performing a portion or all of the noted processes and/or methods. In one or more embodiments, recording medium 804 also stores information which facilitates performing a portion or all of the noted processes and/or methods. In one or more embodiments, recording medium 804 stores library 807 of standard cells including such standard cells as disclosed herein.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 also includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 800.

System 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a UI through I/O interface 810. The information is stored in computer-readable recording medium 804 as user interface (UI) 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

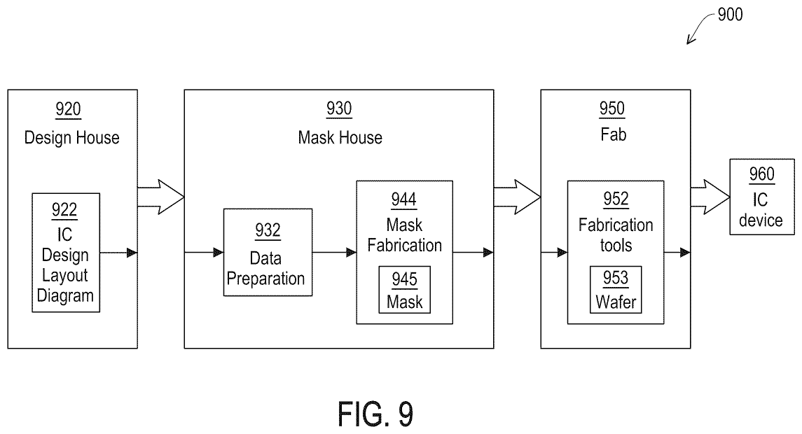

FIG. 9 is a block diagram of an integrated circuit (IC) manufacturing system 900, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 900.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 920 implements a proper design procedure to form IC design layout 922. The design procedure includes one or more of logic design, physical design or place-and-route operation. IC design layout 922 is presented in one or more data files having information of the geometrical patterns. For example, IC design layout 922 can be expressed in a GDSII file format or DFII file format.

Mask house 930 includes data preparation 932 and mask fabrication 944. Mask house 930 uses IC design layout 922 to manufacture one or more masks 945 to be used for fabricating the various layers of IC device 960 according to IC design layout 922. Mask house 930 performs mask data preparation 932, where IC design layout 922 is translated into a representative data file (“RDF”). Mask data preparation 932 provides the RDF to mask fabrication 944. Mask fabrication 944 includes a mask writer. A mask writer converts the RDF to an image on a substrate, such as a mask (reticle) 945 or a semiconductor wafer 953. The design layout 922 is manipulated by mask data preparation 932 to comply with particular characteristics of the mask writer and/or requirements of IC fab 950. In FIG. 9, mask data preparation 932 and mask fabrication 944 are illustrated as separate elements. In some embodiments, mask data preparation 932 and mask fabrication 944 can be collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 922 to compensate for limitations during mask fabrication 944, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to create a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 922.

It should be understood that the above description of mask data preparation 932 has been simplified for the purposes of clarity. In some embodiments, data preparation 932 includes additional features such as a logic operation (LOP) to modify the IC design layout 922 according to manufacturing rules. Additionally, the processes applied to IC design layout 922 during data preparation 932 may be executed in a variety of different orders.

After mask data preparation 932 and during mask fabrication 944, a mask 945 or a group of masks 945 are fabricated based on the modified IC design layout 922. In some embodiments, mask fabrication 944 includes performing one or more lithographic exposures based on IC design layout 922. In some embodiments, an electron-beam (e-beam) or a mechanism of multiple e-beams is used to form a pattern on a mask (photomask or reticle) 945 based on the modified IC design layout 922. Mask 945 can be formed in various technologies. In some embodiments, mask 945 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask can be attenuated PSM or alternating PSM. The mask(s) generated by mask fabrication 944 is used in a variety of processes. For example, such a mask(s) is used in an ion implantation process to form various doped regions in semiconductor wafer 953, in an etching process to form various etching regions in semiconductor wafer 953, and/or in other suitable processes.

IC fab 950 is an IC fabrication business that includes one or more manufacturing facilities for the fabrication of a variety of different IC products. In some embodiments, IC Fab 950 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 950 includes fabrication tools 952 configured to execute various manufacturing operations on semiconductor wafer 953 such that IC device 960 is fabricated in accordance with the mask(s), e.g., mask 945. In various embodiments, fabrication tools 952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 950 uses mask(s) 945 fabricated by mask house 930 to fabricate IC device 960. Thus, IC fab 950 at least indirectly uses IC design layout 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout 922. Semiconductor wafer 953 includes a silicon substrate or other proper substrate having material layers formed thereon. Semiconductor wafer 953 further includes one or more of various doped regions, dielectric features, multilevel interconnects, and the like (formed at subsequent manufacturing steps).

In some embodiments, a read-only memory (ROM) device comprises an active region extending along a first direction, and a plurality of gates extending across and over the active region, along a second direction transverse to the first direction. The plurality of gates correspondingly configures, together with the active region, a plurality of transistors. Each of the plurality of transistors is configured to store a datum. The active region extends continuously across and under more than four conductive gates among the plurality of gates.

In some embodiments, a read-only memory (ROM) device comprises a plurality of instances of a circuit region. The circuit region comprises a plurality of active regions extending continuously along a first direction, and a plurality of gates extending across the plurality of active regions along a second direction transverse to the first direction. The plurality of gates configures, together with the plurality of active regions, a plurality of transistors configured to store data. The plurality of instances of the circuit region comprises first and second instances which abut each other and share a set of source/drains.

A method of manufacturing a read-only memory (ROM) device in accordance with some embodiments comprises forming a plurality of active regions extending continuously along a first direction over a substrate, forming a plurality of gates extending over the plurality of active regions along a second direction transverse to the first direction wherein the plurality of gates configures, together with the plurality of active regions, a plurality of transistors configured to store data, and forming one or more vias over one or more source/drains in the plurality of active regions in accordance with data to be stored in the ROM device. The plurality of active regions, the plurality of gates and the plurality of transistors are arranged in a plurality of instances of a circuit region which comprises at least four adjacent transistors in the first direction. The forming of at least one active region among the plurality of active regions comprises no formation of an isolation structure in the at least one active region between adjacent instances among the plurality of instances.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A read-only memory (ROM) device, comprising:
an active region extending along a first direction; and
a plurality of gates extending across and over the active region, along a second direction transverse to the first direction,
wherein
the plurality of gates correspondingly configures, together with the active region, a plurality of transistors,
each of the plurality of transistors is configured to store a datum, and
the active region extends continuously across and under more than four conductive gates among the plurality of gates.

2. The ROM device of claim 1, further comprising:
a bit line;
a power rail; and
a plurality of word lines correspondingly electrically coupled to the plurality of gates.

3. The ROM device of claim 2, wherein
the plurality of transistors comprises:
a first transistor configured to store a first logic value, the first transistor having a first source/drain electrically coupled to the bit line, and a second source/drain electrically coupled to the power rail,
a second transistor configured to store a second logic value different from the first logic value, the second transistor having first and second source/drains electrically coupled to the bit line, and
a third transistor configured to store the second logic value, the third transistor having first and second source/drains electrically coupled to the power rail.

4. The ROM device of claim 3, wherein
each pair of adjacent transistors among the plurality of transistors shares a common source/drain.

5. The ROM device of claim 3, wherein
the plurality of transistors further comprises at least one of:
a fourth transistor configured to store the second logic value, the fourth transistor having first and second source/drains which are electrically floating,
a fifth transistor configured to store the second logic value, the fifth transistor having a first source/drain electrically coupled to the bit line, and a second source/drain which is electrically floating, or
a sixth transistor configured to store the second logic value, the sixth transistor having a first source/drain electrically coupled to the power rail, and a second source/drain which is electrically floating.

6. The ROM device of claim 5, wherein
each pair of adjacent transistors among the plurality of transistors shares a common source/drain.

7. The ROM device of claim 2, wherein
the bit line and the power rail overlap the active region, and extend continuously along the first direction across the plurality of gates.

8. The ROM device of claim 2, wherein
each of the more than four conductive gates, which the active region extends continuously across and under, is electrically coupled to a corresponding word lines among the plurality of word lines.

9. The ROM device of claim 1, wherein
all gates, across and under which the active region continuously extends, belong to transistors configured to store data.

10. The ROM device of claim 1, wherein
the ROM device is free of an isolation structure that divides the active region into electrically isolated portions.

11. A read-only memory (ROM) device, comprising:
a plurality of instances of a circuit region, wherein
the circuit region comprises:
a plurality of active regions extending continuously along a first direction; and
a plurality of gates extending across the plurality of active regions along a second direction transverse to the first direction, the plurality of gates configuring, together with the plurality of active regions, a plurality of transistors configured to store data,
the plurality of instances of the circuit region comprises first and second instances which abut each other and share a set of source/drains.

12. The ROM device of claim 11, wherein
the plurality of active regions extends continuously from the first instance into the second instance.

13. The ROM device of claim 11, wherein
in the first instance, the plurality of gates comprises a first gate configuring, together with the plurality of active regions, a first set of transistors,
in the second instance, the plurality of gates comprises a second gate configuring, together with the plurality of active regions, a second set of transistors, and
each source/drain in the set of source/drains shared by the first instance and the second instance is a common source/drain of a transistor in the first set and a corresponding transistor in the second set.

14. The ROM device of claim 11, wherein
the plurality of gates comprises first through fourth gates spaced from each other along the first direction by a gate pitch, and
a dimension of the circuit region along the first direction is four times the gate pitch.

15. The ROM device of claim 11, wherein
the plurality of active regions comprises first through fourth active regions spaced from each other along the second direction,
the plurality of gates comprises first through fourth gates spaced from each other along the first direction,
the circuit region further comprises first through fifth sets of source/drains alternatingly arranged with the first through fourth active regions along the first direction, and
each set of the first through fifth sets of source/drains comprises four source/drains correspondingly in the first through fourth active regions.

16. The ROM device of claim 15, wherein
the set of source/drains shared by the first instance and the second instance is one of the first through fifth sets of source/drains in the first instance and is one of the first through fifth sets of source/drains in the second instance.

17. The ROM device of claim 11, wherein
the circuit region further comprises:
a plurality of bit lines and a plurality of power rails extending continuously along the first direction, wherein each bit line among the plurality of bit lines and a corresponding power rail among the plurality of power rails are over a corresponding active region among the plurality of active regions,
a plurality of word line patterns electrically coupled correspondingly to the plurality of gates, and
one or more vias each electrically coupling a source/drain in one active region among the plurality of active regions to the bit line or the power rail over the one active region, in accordance with the data stored in the circuit region.

18. The ROM device of claim 17, wherein
the plurality of gates comprises:
at least one first gate extending continuously along the second direction across all of the plurality of active regions, and
at least one second gate being physically divided into a first gate portion and a second gate portion, the first gate portion extending continuously along the second direction across some of the plurality of active regions, and the second gate portion extending continuously along the second direction across some other of the plurality of active regions.

19. A method of manufacturing a read-only memory (ROM) device, the method comprising:
forming, over a substrate, a plurality of active regions extending continuously along a first direction;
forming a plurality of gates extending over the plurality of active regions along a second direction transverse to the first direction, the plurality of gates configuring, together with the plurality of active regions, a plurality of transistors configured to store data; and
forming one or more vias over one or more source/drains in the plurality of active regions in accordance with data to be stored in the ROM device,
wherein
the plurality of active regions, the plurality of gates and the plurality of transistors are arranged in a plurality of instances of a circuit region which comprises at least four adjacent transistors in the first direction, and
the forming of at least one active region among the plurality of active regions comprises no formation of an isolation structure in the at least one active region between adjacent instances among the plurality of instances.

20. The method of claim 19, further comprising:
depositing and patterning a metal layer to form:
a plurality of word line patterns electrically coupled correspondingly to the plurality of gates, and
a plurality of bit lines and a plurality of power rails extending continuously along the first direction, wherein each bit line among the plurality of bit lines and a corresponding power rail among the plurality of power rails are over a corresponding active region among the plurality of active regions,
wherein each via among the one or more vias electrically couples a corresponding source/drain among the one or more source/drains to a bit line among the plurality of bit lines or a power rail among the plurality of power rails.
